(19) United States
(12) Patent Application Publication
(10) Pub. No.: US 2026/0301675 A1
(43) Pub. Date: Oct. 1, 2026

(54) DISPLAY APPARATUS AND ELECTRONIC DEVICE INCLUDING THE SAME

(71) Applicant: Samsung Display Co., Ltd., Yongin-si (KR)

(72) Inventors: Jongsik Shim, Yongin-si (KR); Wonkyu Kwak, Yongin-si (KR); Doohyun Kim, Yongin-si (KR); Iljoo Kim, Yongin-si (KR)

(21) Appl. No.: 19/562,636

(22) Filed: Mar. 10, 2026

(30) Foreign Application Priority Data
Mar. 27, 2025 (KR) 10-2025-0039696

(51) Int. Cl. G09G 3/3233

(52) U.S. Cl. CPC G09G 3/3233; G09G 2300/0426; G09G 2300/0819; G09G 2300/0842; G09G 2300/0861; G09G 2310/08; G09G 2320/0233

(57) ABSTRACT

A display apparatus and an electronic device including the same are provided. The display apparatus including: a substrate including a first display area and a second display area, the second display area including a circuit area and a transmission area; a first pixel circuit in the first display area, and a first light-emitting diode electrically connected to the first pixel circuit; and a second pixel circuit in the second display area, and a second light-emitting diode electrically connected to the second pixel circuit, wherein each of the first pixel circuit and the second pixel circuit includes: a driving transistor including a gate electrically connected to a first node, a first terminal electrically connected to a second node, and a second terminal electrically connected to a third node; a data writing transistor electrically connected between a data line and the first node.

### CROSS-REFERENCE TO RELATED APPLICATION

This application claims priority to and the benefit of Korean Patent Application No. 10-2025-0039696, filed on Mar. 27, 2025, in the Korean Intellectual Property Office, the entire disclosure of which is incorporated by reference herein.

### BACKGROUND

### 1. Field

One or more embodiments relate to a display apparatus and an electronic device including the same.

### 2. Description of the Related Art

A display apparatus includes a display panel, and the display panel includes a display element that implements a pixel and a pixel circuit for controlling an electrical signal applied to the display element. The pixel circuit may include transistors, at least one capacitor, and a plurality of wires.

Recently, the uses of display apparatuses have become more diverse. Furthermore, the display apparatuses are becoming thinner and lighter, and the range of application thereof has expanded. As the display apparatuses are utilized in various electronic devices, the functions integrated or linked to the display apparatuses are increasing.

### SUMMARY

An area where a component (for example, an electronic component) is disposed may include a transmission area through which light emitted from the component and/or light directed toward the component may be transmitted. Therefore, a smaller number of pixels are arranged in the area where the component is disposed compared to a surrounding display area, so a difference in luminance may be perceived by a user.

One or more embodiments of the present disclosure include a display apparatus that displays a high-quality image by improving the luminance of the area where the component is disposed, and an electronic device including the same. However, such an aspect is an example, and the scope of the present disclosure is not limited thereby.

Additional aspects and features will be set forth in part in the description which follows and, in part, will be apparent from the description, or may be learned by practice of the presented embodiments of the present disclosure.

According to one or more embodiments, a display apparatus including: a substrate including a first display area and a second display area, the second display area including a circuit area and a transmission area; a first pixel circuit in the first display area, and a first light-emitting diode electrically connected to the first pixel circuit; and a second pixel circuit in the second display area, and a second light-emitting diode electrically connected to the second pixel circuit, wherein each of the first pixel circuit and the second pixel circuit includes: a driving transistor including a gate electrically connected to a first node, a first terminal electrically connected to a second node, and a second terminal electrically connected to a third node; a data writing transistor electrically connected between a data line and the first node; a first emission control transistor electrically connected between a driving voltage line and the second node; and a second emission control transistor electrically connected between the third node and a corresponding light-emitting diode from among the first light-emitting diode and the second light-emitting diode, and wherein the second emission control transistor of the second pixel circuit is maintained in a turn-on state for one frame.

According to one or more embodiments, the first emission control transistor of each of the first pixel circuit and the second pixel circuit is turned on or turned off according to a first emission control signal; the second emission control transistor of the first pixel circuit is turned on or turned off according to a second emission control signal that is different from the first emission control signal; and the second emission control transistor of the second pixel circuit is turned on according to a third emission control signal.

According to one or more embodiments, the one frame includes a first scan period and at least one second scan period; the first scan period includes a first period in which the second emission control signal is supplied as an off voltage; and during the at least one second scan period, the second emission control signal is supplied as an on voltage.

According to one or more embodiments, wherein the third emission control signal is supplied as the on voltage during the first scan period and the at least one second scan period.

According to one or more embodiments, the driving transistor includes an oxide semiconductor layer.

According to one or more embodiments, the first emission control transistor includes a silicon semiconductor layer.

According to one or more embodiments, each of the first pixel circuit and the second pixel circuit further includes: a first initialization transistor electrically connected between a reference voltage line and the driving transistor; and a second initialization transistor electrically connected between an initialization voltage line and the corresponding light-emitting diode from among the first light-emitting diode and the second light-emitting diode.

According to one or more embodiments, a display apparatus including: a substrate including a first display area and a second display area, the second display area including a circuit area and a transmission area; a first pixel circuit in the first display area, and a first light-emitting diode connected to the first pixel circuit; and a second pixel circuit in the second display area, and a second light-emitting diode electrically connected to the second pixel circuit, wherein each of the first pixel circuit and the second pixel circuit includes: a driving transistor including a gate electrically connected to a first node, a first terminal electrically connected to a second node, and a second terminal electrically connected to a third node; a data writing transistor electrically connected between a data line and the first node; and a first emission control transistor electrically connected between a driving voltage line and the second node, wherein the first pixel circuit further includes a second emission control transistor electrically connected between the first light-emitting diode and the third node, and
wherein the third node of the second pixel circuit and the second light-emitting diode are electrically connected via a conductive line.

According to one or more embodiments, the second pixel circuit further includes a third emission control transistor, the third emission control transistor being electrically connected between the second light-emitting diode and the third node and including a gate electrode and a semiconductor layer disposed below the gate electrode.

According to one or more embodiments, the semiconductor layer of the third emission control transistor includes a channel region overlapping the gate electrode, and a source region and a drain region on opposite sides of the channel region; and the conductive line electrically connects the source region and the drain region of the third emission control transistor.

According to one or more embodiments, the second emission control transistor in the first pixel circuit includes a first semiconductor layer including a gate electrode, a channel region overlapping the gate electrode, and a source region and a drain region on opposite sides of the channel region; and the conductive line in the second pixel circuit including a second semiconductor layer having a shape corresponding to the first semiconductor layer.

According to one or more embodiments, the display apparatus further including: an emission control line configured to transmit an emission control signal to the gate electrode of the second emission control transistor, wherein the emission control line crosses over the second semiconductor layer.

According to one or more embodiments, the display apparatus further including: an emission control line configured to transmit an emission control signal to the gate electrode of the second emission control transistor; and an auxiliary emission control line between the substrate and the second semiconductor layer, wherein the emission control line is electrically connected to the auxiliary emission control line.

According to one or more embodiments, the driving transistor includes an oxide semiconductor layer.

According to one or more embodiments, the first emission control transistor includes a silicon semiconductor layer.

According to one or more embodiments, each of the first pixel circuit and the second pixel circuit further includes: a first initialization transistor electrically connected between a reference voltage line and the driving transistor; and a second initialization transistor electrically connected between an initialization voltage line and a corresponding light-emitting diode from among the first light-emitting diode and the second light-emitting diode.

According to one or more embodiments, an electronic device including: a display apparatus configured to display images; a memory to store an application; and a processor configured to execute the application and transmit an image data signal or a control signal to the display apparatus, wherein the display apparatus includes: a substrate including a first display area and a second display area, the second display area including a circuit area and a transmission area; a first pixel circuit in the first display area, and a first light-emitting diode connected to the first pixel circuit; and a second pixel circuit in the second display area, and a second light-emitting diode electrically connected to the second pixel circuit, wherein each of the first pixel circuit and the second pixel circuit includes: a driving transistor including a gate electrically connected to a first node, a first terminal electrically connected to a second node, and a second terminal electrically connected to a third node; a data writing transistor electrically connected between a data line and the first node; and a first emission control transistor electrically connected between a driving voltage line and the second node, wherein the first pixel circuit further includes a second emission control transistor electrically connected between the first light-emitting diode and the third node, and wherein the third node of the second pixel circuit and the second light-emitting diode are electrically connected by a conductive path.

According to one or more embodiments, the second pixel circuit further includes a third emission control transistor electrically connected between the second light-emitting diode and the third node of the second pixel circuit; and the third emission control transistor is maintained in a turn-on state.

According to one or more embodiments, the third node of the second pixel circuit and the second light-emitting diode are electrically connected via a conductive line.

According to one or more embodiments, the driving transistor includes an oxide semiconductor layer.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a schematic block diagram of a display apparatus according to one or more embodiments;

FIG. 2 is a schematic plan view of a display panel according to one or more embodiments;

FIG. 3 is a schematic cross-sectional view of a display apparatus according to one or more embodiments;

FIG. 4 is a schematic plan view of a portion of a display panel according to one or more embodiments;

FIG. 5 is a schematic plan view of a pixel arrangement disposed in a first display area according to one or more embodiments;

FIG. 6 is a schematic plan view of a pixel arrangement disposed in a second display area according to one or more embodiments;

FIG. 7 is an equivalent circuit diagram of a main pixel according to one or more embodiments;

FIG. 8 is an equivalent circuit diagram of an auxiliary pixel according to one or more embodiments;

FIG. 9 is a diagram schematically showing signals supplied to the main pixel of FIG. 7;

FIG. 10 is a diagram schematically showing signals supplied to the auxiliary pixel of FIG. 8;

FIG. 11 is an equivalent circuit diagram of an auxiliary pixel according to one or more embodiments;

FIG. 12A is a schematic cross-sectional view of a first display area of a display panel according to one or more embodiments, and FIG. 12B is a schematic cross-sectional view of a second display area of a display panel according to one or more embodiments;

FIG. 13 is an equivalent circuit diagram of an auxiliary pixel according to one or more embodiments;

FIGS. 14 and 15 are schematic cross-sectional views, each illustrating a second display area of a display panel according to one or more embodiments;

FIGS. 16A, 16B, and 16C are graphs illustrating driving currents of a main pixel circuit and an auxiliary pixel circuit, according to one or more embodiments, with respect to data voltage;

FIG. 17 is a schematic block diagram of an electronic device according to one or more embodiments; and

FIGS. 18, 19, and 20 are schematic drawings of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present disclosure. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or variations thereof.

Effects, aspects, and features of the present disclosure, and methods for achieving them will be clarified with reference to embodiments described below in detail with reference to the drawings.

In the specification, the terms “first,” “second,” etc., are not used in a restrictive sense but are used for distinguishing one component from another.

In the specification, singular expressions include plural expressions unless the context clearly indicates otherwise.

The terms “include” and “have” as used in the specification mean that a feature or component described in the specification exists, and do not preclude the possibility that one or more other features or components may be added.

In the specification, it will be further understood that, when a layer, region, or component is referred to as being “on” another layer, region, or component, it may be directly on the other layer, region, or component, or may be indirectly on the other layer, region, or component with intervening layers, regions, or components therebetween.

In the specification, it will be understood that when a layer, a region, or a component is referred to as being “connected” to another layer, region, or component, it may be “directly connected” to the other layer, region, or component and/or may be “indirectly connected” to the other layer, region, or component with other layers, regions, or components interposed therebetween. For example, when a layer, a region, or a component is referred to as being “electrically connected,” it may be directly electrically connected, and/or may be indirectly electrically connected with intervening layers, regions, or components therebetween.

In the specification, the x-direction, y-direction, and z-direction are not limited to directions along the three axes on the orthogonal coordinate system, and may be interpreted in a broad sense. For example, the x-direction, y-direction, and z-direction may be orthogonal to each other, but they may also refer to different directions that are not orthogonal to each other.

In the specification, when a component is seen in a “plan view,” it means that the component is seen from above (e.g., the component is seen in a direction perpendicular to a top surface of a substrate), and when a component is seen in a “cross-sectional view,” it means that the component is cut vertically and seen from the side.

In the specification, when a first component “overlaps” a second component, it means that the first component is located above or below the second component so that at least a portion of the first component overlaps the second component in a plan view.

In the specification, “ON” or “on” used in association with an element state may be referred to as an activated state of an element, and “OFF” or “off” may be referred to as an inactivated state of an element. “ON” or “on” used in association with a signal received by an element may be referred to as a signal for activating the element, and “OFF” or “off” may be referred to as a signal for inactivating the element. The device may be activated by a high-level voltage or a low-level voltage. For example, a P-channel transistor (P-type transistor) is activated by a low-level voltage, and an N-channel transistor (N-type transistor) is activated by a high-level voltage. Therefore, it is important to understand that the “on” voltages for P-type and N-type transistors are opposite (low vs. high) voltage levels.

In this specification, when a certain embodiment may be implemented differently, a specific process order may be performed differently from the described order. For example, two consecutively described processes may be performed substantially at the same time or performed in an order opposite to the described order.

Also, for convenience of explanation, components in the drawings may have exaggerated or reduced sizes. For example, the size and thickness of each component shown in the drawing are arbitrarily shown for convenience of explanation, and thus the present disclosure is not necessarily limited to what is shown.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

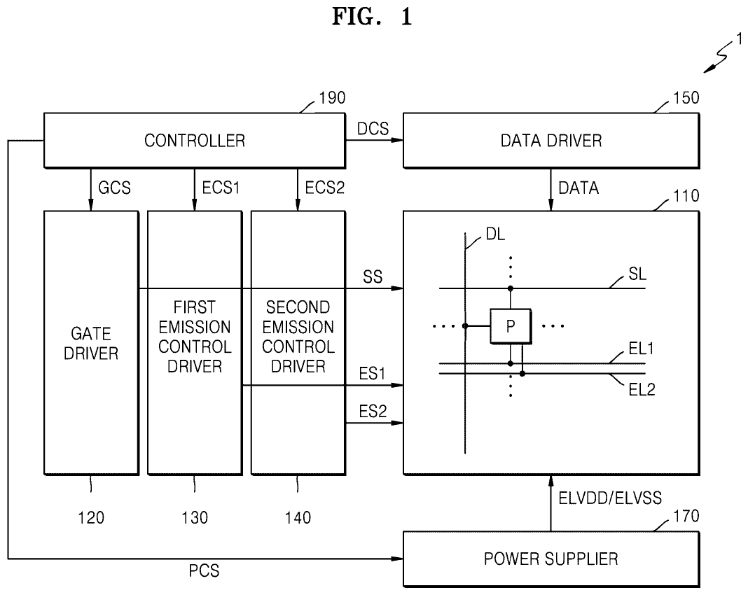

FIG. 1 is a schematic block diagram of a display apparatus 1 according to one or more embodiments.

Referring to FIG. 1, the display apparatus 1 may include a pixel unit 110, a gate driver 120, a first emission control driver 130, a second emission control driver 140, a data driver 150, a power supplier 170, and a controller 190.

A plurality of scan lines SL, a plurality of first emission control lines EL1, a plurality of second emission control lines EL2, a plurality of data lines DL, a plurality of voltage lines, and a plurality of pixels P connected to these lines may be disposed in the pixel unit 110. The pixels P may be disposed in various arrangements according to specific rules to display an image. For example, the pixels P may be arranged in various configurations such as a PENTILE® (diamond) arrangement, a stripe arrangement, a mosaic arrangement, or a delta arrangement. PENTILE® is a registered trademark of Samsung Display Co., Ltd., Republic of Korea. Each pixel P may include an organic light-emitting diode (OLED) as a display element (e.g., a light-emitting diode), and the organic light-emitting diode (OLED) may be electrically connected to a pixel circuit. The pixel circuit may include a plurality of transistors and at least one capacitor. A pixel P may emit red, green, blue, or white light via an organic light-emitting diode (OLED). Each pixel P may be electrically connected to at least one corresponding scan line from among the scan lines SL, a corresponding first emission control line from among the first emission control lines EL1, a corresponding second emission control line from among the second emission control lines EL2, and a corresponding data line from among the data lines DL.

The scan lines SL may each extend in a row direction and may be electrically connected to pixels P arranged in a same row. Each of the scan lines SL may transmit a scan signal SS to the pixels P in the same row. Each of the first emission control lines EL1 and the second emission control lines EL2 may extend in the row direction and may be electrically connected to the pixels P arranged in the same row. The first emission control lines EL1 may each transmit a first emission control signal ES1 to the pixels P arranged in the same row, and the second emission control lines EL2 may each transmit a second emission control signal ES2 to the pixels P arranged in the same row.

The data lines DL may each extend in a column direction and may be electrically connected to pixels P arranged in a same column. Each of the data lines DL may transmit a data signal DATA corresponding to each of the pixels P in the same column in synchronization with a scan signal SS.

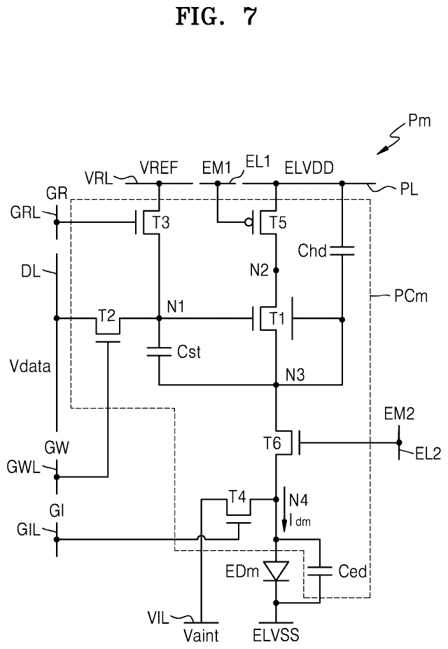

The gate driver 120, electrically connected to the plurality of scan lines SL, may generate scan signals SS in response to a control signal GCS from the controller 190, and may sequentially supply the same to the scan lines SL. A scan line SL may be electrically connected to a gate of a data writing transistor included in each pixel P. The scan signal SS may be a gate control signal that controls turn-on and turn-off of the data writing transistor. A data writing transistor refers to a transistor (e.g., a second transistor T2 of FIG. 7) that is electrically connected between a data line DL and a driving transistor of a pixel circuit.

The first emission control driver 130, electrically connected to a plurality of first emission control lines EL1, may generate first emission control signals ES1 in response to a control signal ECS1 from the controller 190, and may sequentially supply the same to the first emission control lines EL1. The first emission control signal ES1 may be a gate control signal that controls turn-on and turn-off of the first emission control transistor included in each pixel P. The first emission control transistor refers to a transistor (e.g., a fifth transistor T5 of FIG. 7) that is electrically connected between a driving voltage line that transmits a first driving voltage ELVDD and the driving transistor of the pixel circuit.

The second emission control driver 140, electrically connected to a plurality of second emission control lines EL2, may generate second emission control signals ES2 in response to a control signal ECS2 from the controller 190, and may sequentially supply the same to the second emission control lines EL2. The second emission control signal ES2 may be a gate control signal that controls turn-on and turn-off of the second emission control transistor included in each pixel P. The second emission control transistor refers to a transistor (e.g., a sixth transistor T6 of FIG. 7) that is electrically connected between the driving transistor of the pixel circuit and the light-emitting diode.

Each of the scan signals SS, the first emission control signals ES1, and the second emission control signals ES2 may be a square wave signal including an on voltage that may turn on a corresponding transistor and an off voltage that may turn off the corresponding transistor.

In FIG. 1, the pixel P is illustrated as being connected to a scan line SL, a first emission control line EL1 and a second emission control line EL2, but this is merely an example, and the pixel P may be electrically connected to more gate control lines, and the display apparatus 1 may further include drivers that output gate control signals having different timings at which on voltages are applied.

The data driver 150, electrically connected to the plurality of data lines DL, may supply data signals DATA to the data lines DL in response to a control signal DCS from the controller 190. A data signal DATA supplied to a data line DL may be supplied to a pixel P supplied with a scan signal SS of on voltage. The data driver 150 may convert input image data having grayscale information from the controller 190 into data signals DATA in the form of voltage or current.

The power supplier 170 may generate voltages for driving pixels P in response to a control signal PCS from the controller 190. The power supplier 170 may generate the first driving voltage ELVDD and a second driving voltage ELVSS and supply them to the pixels P. The first driving voltage ELVDD may be a high-level voltage supplied to the first electrode (e.g., pixel electrode, or anode) of the light-emitting diode included in the pixel P. The second driving voltage ELVSS may be a low-level voltage supplied to the second electrode (e.g., opposite electrode, or cathode) of the light-emitting diode included in the pixel P.

The controller 190 may generate control signals GCS, ECS1, ECS2, DCS, and PCS based on signals input from the outside (e.g., processor), and supply them to the gate driver 120, the first emission control driver 130, the second emission control driver 140, the data driver 150, and the power supplier 170, respectively. Each of the control signals GCS, ECS1, and ECS2 respectively output to the gate driver 120, the first emission control driver 130, and the second emission control driver 140 may include a plurality of clock signals and a gate start signal. The control signal DCS output to the data driver 150 may include clock signals and a source start signal.

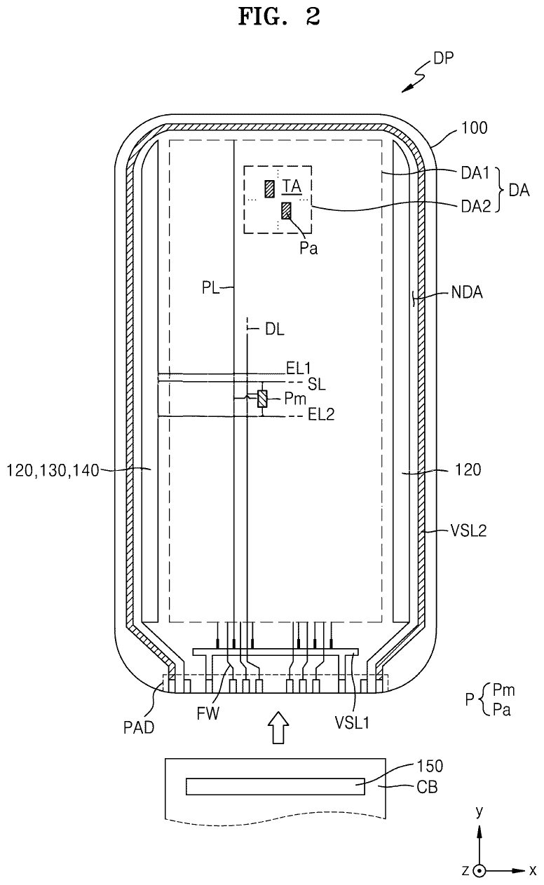

FIG. 2 is a schematic plan view of a display panel DP according to one or more embodiments.

Referring to FIG. 2, the display apparatus 1 (see FIG. 1) may include a display panel DP, and the display panel DP may include a substrate 100. Various components forming the display panel DP may be disposed on a substrate 100. The substrate 100 includes a display area DA and a non-display area NDA (e.g., peripheral area) around (e.g., surrounding) the display area DA along an edge or a periphery of the display area DA. The display area DA may include a first display area DA1 for displaying a main image, and a second display area DA2 for displaying an auxiliary image and including a transmission area TA. The auxiliary image may form a single overall image together with the main image, or the auxiliary image may be an image independent from the main image.

The second display area DA2 may be an area that overlaps components such as a camera or sensor disposed under the display panel DP. The second display area DA2 may be disposed inside the first display area DA1 and may be at least partially surrounded by the first display area DA1. In one or more embodiments, the second display area DA2 may be disposed on one side of the first display area DA1.

A plurality of pixels P may be disposed in the display area DA. The pixels P may include a plurality of main pixels Pm disposed in a first display area DA1 and a plurality of auxiliary pixels Pa disposed in a second display area DA2. Each of the main pixels Pm and auxiliary pixels Pa may include a light-emitting diode that emits red, green, blue, or white light, and the light-emitting diode may be electrically connected to a pixel circuit.

The second display area DA2 may have a transmission area TA through which light is transmitted. The transmission area TA may be an area in which no light-blocking elements are disposed in the second display area DA2. For example, transistors, capacitors, etc. may not be disposed in the transmission area TA. The transmission area TA may be an area in which pixel circuits of auxiliary pixels Pa are not disposed in the second display area DA2.

The pixels P may be electrically connected to drivers and lines disposed in the non-display area NDA. A gate driver 120, a first emission control driver 130, a second emission control driver 140, a first voltage supply line VSL1, a second voltage supply line VSL2, and a pad unit PAD may be disposed in the non-display area NDA.

Part or all of each of the gate driver 120, the first emission control driver 130, and the second emission control driver 140 may be formed directly in the non-display area NDA during the process of forming the pixel circuits in the display area DA.

The gate driver 120 may supply the scan signal SS (see FIG. 1) to each of the pixel circuits that drive the pixels P through the scan line SL. The first emission control driver 130 may supply the first emission control signal ES1 (see FIG. 1) to each of the pixel circuits that drive the pixels P through the first emission control line EL1. The second emission control driver 140 may supply the second emission control signal ES2 (see FIG. 1) to each of the pixel circuits that drive the pixels P through the second emission control line EL2.

In one or more embodiments, the gate driver 120 may be disposed on opposite sides of the non-display area NDA with the display area DA therebetween. Some of the pixels P may be electrically connected to a gate driver 120 disposed on the left side (−x direction (i.e., a direction opposite to a x direction)) of the non-display area NDA, and the remainder of the pixels P may be electrically connected to a gate driver 120 disposed on the right side (+x direction (i.e., the x direction)) of the non-display area NDA. In one or more embodiments, the gate driver 120 may be disposed only on one side of the non-display area NDA.

In one or more embodiments, each of the first emission control driver 130 and the second emission control driver 140 may be disposed on one side of the non-display area NDA. In one or more embodiments, each of the first emission control driver 130 and the second emission control driver 140 may be disposed on both sides of the non-display area NDA with the display area DA therebetween. In one or more embodiments, the first emission control driver 130 may be disposed on one side of the non-display area NDA, and the second emission control driver 140 may be disposed on the opposite side of the non-display area NDA.

The pad unit PAD may be disposed on one side of the substrate 100. The pad unit PAD is exposed and not covered by insulating layers, so it may be connected to a circuit board CB. In one or more embodiments, the circuit board CB may be a flexible printed circuit board (FPCB). Each of the data driver 150, the power supplier 170 (see FIG. 1), and the controller 190 (see FIG. 1) may be formed as discrete integrated circuit chips or as a single integrated circuit chip and disposed on a circuit board CB. In one or more embodiments, some or all of the data driver 150, power supplier 170, and controller 190 may be directly disposed on the substrate 100 using a chip-on-glass (COG) or chip-on-plastic (COP) method.

The data driver 150 may output data signals DATA (see FIG. 1), and the data signals DATA may be transmitted to the pixel circuits of the pixels P through the fan-out lines FW and the data lines DL electrically connected to the fan-out lines FW.

The power supplier 170 may supply a first driving voltage ELVDD to a first voltage supply line VSL1 and a second driving voltage ELVSS to a second voltage supply line VSL2. The first driving voltage ELVDD may be transmitted to pixel circuits of pixels P through a driving voltage line PL electrically connected to the first voltage supply line VSL1, and the second driving voltage ELVSS may be transmitted to the second electrode (opposite electrode) of the light-emitting diode of pixels P by being electrically connected to the second voltage supply line VSL2.

The first voltage supply line VSL1 may extend in the first direction (x direction) from the lower side (−y direction (i.e., a direction opposite to a y direction)) of the display area DA. The second voltage supply line VSL2 may have a loop shape with one side open and may at least partially be around (e.g., surround) the display area DA.

The second display area DA2 may have a circular, elliptical or polygonal shape in a plan view (e.g., when viewed from a direction approximately perpendicular to the substrate 100). Although FIG. 2 illustrates an embodiment with a single second display area DA2, a plurality of second display areas DA2 may be provided. A plurality of second display areas DA2 may be disposed spaced apart from each other. The plurality of second display areas DA2 may have different shapes and sizes.

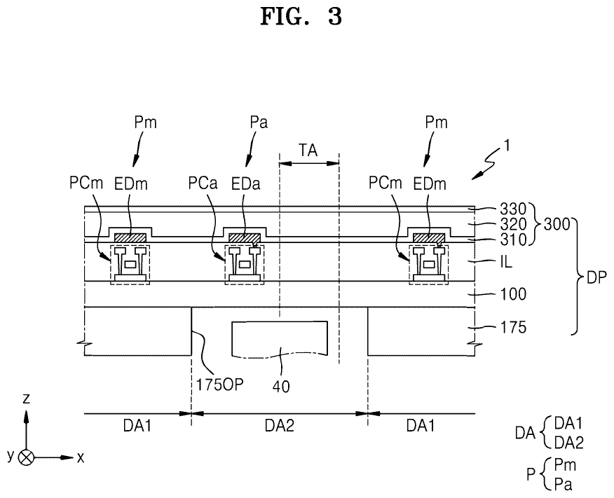

FIG. 3 is a schematic cross-sectional view of a display apparatus 1 according to one or more embodiments.

Referring to FIG. 3, the display apparatus 1 may include a display panel DP and a component 40 that overlaps the display panel DP and is disposed on the lower surface of the display panel DP. The component 40 may be disposed to correspond to the second display area DA2. That is, in a plan view, the component 40 may be disposed overlapping the second display area DA2.

A display panel DP may include a substrate 100, pixel circuits PCm and PCa disposed on the substrate 100, light-emitting diodes EDm and EDa disposed on the pixel circuits PCm and PCa, and a thin film encapsulation layer 300 covering the light-emitting diodes EDm and EDa.

The substrate 100 may include glass or a polymer resin. A substrate 100 including a polymer resin may be flexible, foldable, rollable, and/or bendable. The substrate 100 may have a multilayer structure including a layer including the polymer resin and an inorganic layer.

A lower protective film 175 may be disposed on the lower surface (the surface in the −z direction (i.e., a direction opposite to a z direction)) of the substrate 100. The lower protective film 175 may be attached to the lower surface of the substrate 100. An adhesive layer may be interposed between the lower protective film 175 and the substrate 100. Alternatively, the lower protective film 175 may be formed directly on the lower surface of the substrate 100, in which case an adhesive layer may not be interposed between the lower protective film 175 and the substrate 100.

The lower protective film 175 may serve to support and protect the substrate 100. The lower protective film 175 may define an opening 175OP corresponding to the second display area DA2. In a plan view, the opening 175OP of the lower protective film 175 may be disposed to overlap the second display area DA2. The lower protective film 175 may include an organic insulating material such as polyethylene terephthalate (PET) or polyimide (PI).

The main pixels Pm and auxiliary pixels Pa may be disposed on the upper surface (the surface in the +z direction (i.e., the z direction)) of the substrate 100. The main pixels Pm may be disposed in the first display area DA1 and each of the main pixels Pm may include a main pixel circuit PCm (e.g., a first pixel circuit) and a main light-emitting diode EDm (e.g., a first light-emitting diode) electrically connected to the main pixel circuit PCm. The auxiliary pixels Pa may be disposed in the second display area DA2 and each of the auxiliary pixels Pa may include an auxiliary pixel circuit PCa (e.g., second pixel circuit) and an auxiliary light-emitting diode EDa (e.g., second light-emitting diode) electrically connected to the auxiliary pixel circuit PCa.

Each of the main light-emitting diode EDm and the auxiliary light-emitting diode EDa may be an organic light-emitting diode (OLED) comprising an organic material. Alternatively, each of the main light-emitting diode EDm and the auxiliary light-emitting diode EDa may be an inorganic light-emitting diode comprising an inorganic material. The inorganic light-emitting diode may include a PN junction diode comprising inorganic semiconductor-based materials. When a forward voltage is applied to a PN junction diode, holes and electrons are injected, and the recombination thereof generates energy converted into light energy, enabling emission of light of a certain color. The width of the light-emitting diodes described above may range from several to several hundred micrometers or from several to several hundred nanometers. In one or more embodiments, each of the main light-emitting diode EDm and the auxiliary light-emitting diode EDa may include a quantum dot light-emitting diode. An emission layer of each of the main light-emitting diode EDm and the auxiliary light-emitting diode EDa may include an organic material, an inorganic material, quantum dots, an organic material and quantum dots, or an inorganic material and quantum dots.

The main light-emitting diode EDm may be electrically connected to the main pixel circuit PCm disposed underneath the main light-emitting diode EDm, and the auxiliary light-emitting diode EDa may be electrically connected to an auxiliary pixel circuit PCa disposed underneath the auxiliary light-emitting diode EDa. Insulating layers IL may be disposed between components constituting each of the main pixel circuit PCm and the auxiliary pixel circuit PCa, such as semiconductor layers and conductive layers.

The second display area DA2 may include a transmission area TA. The transmission area TA may be an area in which pixel circuit elements such as transistors and capacitors are not disposed, and may be an area with high light transmittance.

In one or more embodiments, the auxiliary pixel circuit PCa and the auxiliary light-emitting diode EDa may not be arranged in the transmission area TA. The transmission area TA may be an area for transmitting light emitted from the component 40 and/or light directed toward the component 40. In the display panel DP, the transmittance of the transmission area TA may be about 30% or more, about 40% or more, about 50% or more, about 60% or more, about 70% or more, about 75% or more, about 80% or more, about 85% or more, or about 90% or more.

The component 40 may include a sensor such as a proximity sensor, a light sensor, an iris sensor, a facial recognition sensor, and a camera (or image sensor). The component 40 may be configured to emit or receive light in the infrared, ultraviolet, and visible light bands.

The thin film encapsulation layer 300 may cover light-emitting diodes EDm and EDa. The thin film encapsulation layer 300 may include at least one inorganic encapsulation layer and at least one organic encapsulation layer. In one or more embodiments, the thin film encapsulation layer 300 may include a first inorganic encapsulation layer 310, a second inorganic encapsulation layers 330, and an organic encapsulation layer 320 therebetween.

An input sensing layer and/or an optical function layer may be disposed on the thin film encapsulation layer 300. The input sensing layer may sense an external input, such as a touch by an object like a finger or a stylus pen. The input sensing layer may be configured to sense the external input by a mutual-capacitance and/or self-capacitance method. The optical function layer may include an anti-reflection layer for reducing the reflectivity of light incident on the display apparatus 1. In one or more embodiments, the optical function layer may include a black matrix and color filters.

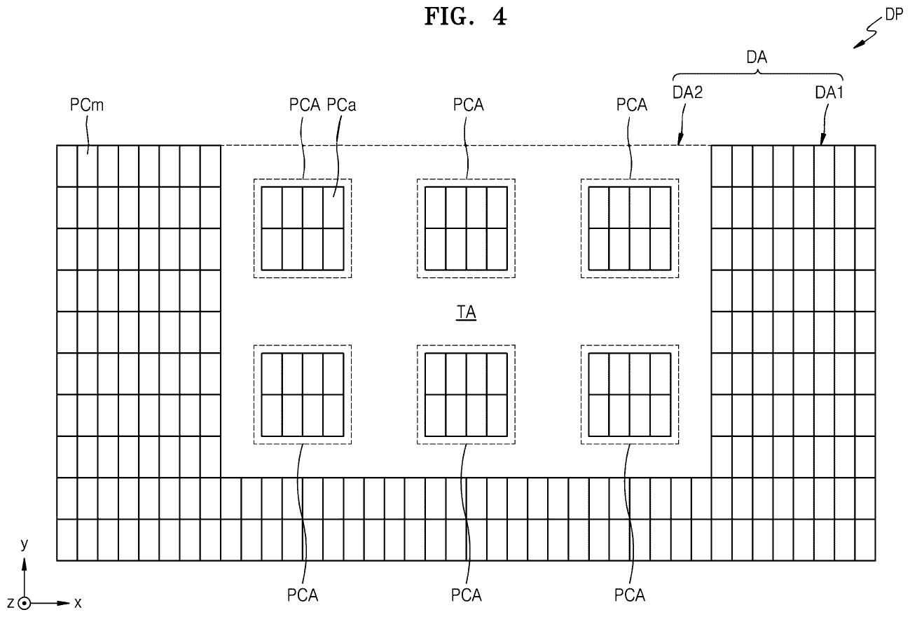

FIG. 4 is a schematic plan view of a portion of a display panel DP according to one or more embodiments.

Referring to FIG. 4, the display panel DP may include a display area DA. The display area DA may include a first display area DA1 and a second display area DA2 including a circuit area PCA and a transmission area TA. Because the components of the display panel DP are disposed on a substrate 100 (see FIG. 2), it may be said that the substrate 100 includes the first display area DA1 and the second display area DA2 including the circuit area PCA and the transmission area TA.

Main pixel circuits PCm may be disposed in the first display area DA1. The main pixel circuits PCm may be disposed in a matrix form along the first direction (x direction) and the second direction (y direction). For example, the main pixel circuits PCm may be disposed along rows and columns of a matrix along the first direction (x direction) and the second direction (y direction).

At least a portion of the second display area DA2 may be surrounded by the first display area DA1. The second display area DA2 may have various shapes in a plan view, such as a circular, elliptical, or polygonal shape. In this regard, FIG. 4 illustrates a case where the second display area DA2 has a rectangle shape in a plan view.

The second display area DA2 may include circuit areas PCA in which auxiliary pixel circuits PCa are disposed, and the transmission area TA outside the circuit areas PCA. Pixel circuits may not be disposed in the transmission area TA. In one or more embodiments, the circuit areas PCA may be spaced (e.g., spaced apart) from each other with the transmission area TA therebetween. Each of the circuit areas PCA may be surrounded by the transmission area TA. In one or more embodiments, a plurality of transmission areas TA are provided. The circuit areas PCA and the transmission areas TA may be disposed alternately along the first direction (x direction) and/or the second direction (y direction). In this manner, the arrangement of the circuit areas PCA and the transmission area TA may be designed in various ways.

In one or more embodiments, the main pixel circuit PCm and the auxiliary pixel circuit PCa may be identical (e.g., substantially the same) in configuration. In one or more embodiments, the main pixel circuit PCm and the auxiliary pixel circuit PCa may be different in configuration.

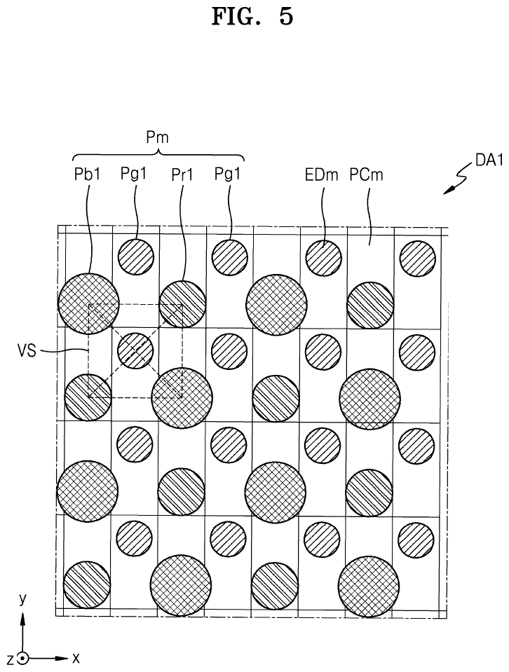

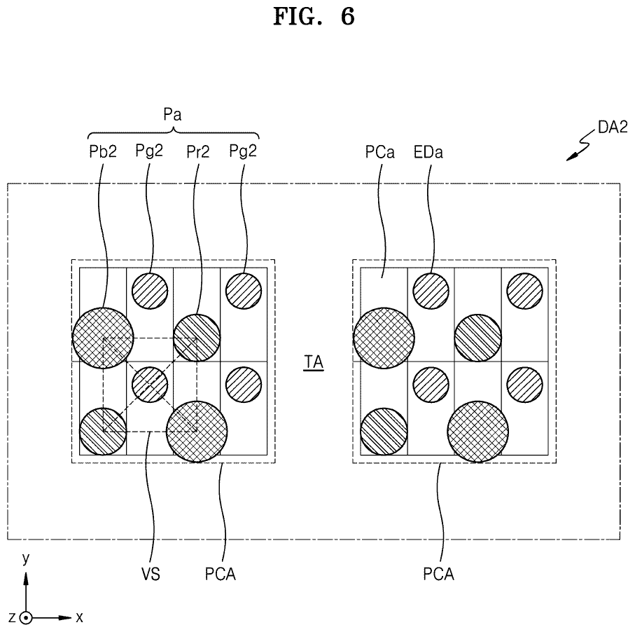

FIG. 5 is a schematic plan view of a pixel arrangement disposed in a first display area DA1 according to one or more embodiments, and FIG. 6 is a schematic plan view of a pixel arrangement disposed in a second display area DA2 according to one or more embodiments.

Referring to FIG. 5, main pixels Pm may be disposed in the first display area DA1. In the specification, each of the main pixels Pm represents a sub-pixel, which is the smallest element that implements an image. Each of the main pixels Pm may include a main light-emitting diode EDm and a main pixel circuit PCm electrically connected to the main light-emitting diode EDm. The boundary of each of the main pixels Pm illustrated in FIG. 5 represents the emission area of the main light-emitting diode EDm included in the main pixel Pm.

The main pixels Pm may include a first red pixel Pr1, a first blue pixel Pb1, and a first green pixel Pg1. The first red pixel Pr1 may emit red light, the first blue pixel Pb1 may emit blue light, and the first green pixel Pg1 may emit green light.

In one or more embodiments, the size (or area) of the first blue pixel Pb1 may be larger than the size (or area) of the first red pixel Pr1 and the size (or area) of the first green pixel Pg1. The size (or area) of the first red pixel Pr1 may be greater than or equal to the size (or area) of the first green pixel Pg1.

The main pixels Pm may be arranged in a PENTILE® arrangement. For example, first green pixels Pg1 may be disposed in the first row, first blue pixels Pb1 and first red pixels Pr1 may be disposed alternately in the second row, first green pixels Pg1 may be disposed in the third row, and first red pixels Pr1 and first blue pixels Pb1 may be disposed alternately in the fourth row. This arrangement of pixels may be repeated in units of four rows.

In this case, the first green pixels Pg1 in odd-numbered rows and the first blue pixels Pb1 and the first red pixels Pr1 in even-numbered rows may be staggered. For example, first blue pixels Pb1 and first red pixels Pr1 may be disposed alternately in the first column, first green pixels Pg1 may be disposed in the second column, first red pixels Pr1 and first blue pixels Pb1 may be disposed alternately in the third column, and first green pixels Pg1 may be arranged in the fourth column. This arrangement of pixels may be repeated in units of four columns.

For example, among the vertices of a virtual square VS with the center point of the first green pixel Pg1 as the center point of the square, a first blue pixel Pb1 may be disposed at the first and third vertices that face each other, and a first red pixel Pr1 may be disposed at the remaining vertices, the second and fourth vertices. Here, the virtual square VS may be changed into various shapes such as a rectangle, a rhombus, and a square.

Although, FIG. 5 illustrates that the main pixels Pm are arranged in a PENTILE® arrangement, the present disclosure is not limited thereto. For example, the main pixels Pm may be disposed in various configurations such as a stripe arrangement, a mosaic arrangement, and a delta arrangement.

In one or more embodiments, the main pixels Pm may have a circular shape in a plan view. In one or more embodiments, the main pixels Pm may have various shapes in a plan view, such as a polygonal or elliptical shape, etc.

Referring to FIG. 6, auxiliary pixels Pa may be disposed in the second display area DA2. Here, each of the auxiliary pixels Pa represents a sub-pixel, which is the smallest element that implements an image. Each of the auxiliary pixels Pa may include an auxiliary light-emitting diode EDa and an auxiliary pixel circuit PCa electrically connected to the auxiliary light-emitting diode EDa. The boundary of each of the auxiliary pixels Pa illustrated in FIG. 6 represents the emission area of auxiliary light-emitting diode EDa included in the auxiliary pixel Pa.

The auxiliary pixels Pa may include second red pixels Pr2, second blue pixels Pb2, and second green pixels Pg2. The second red pixel Pr2 may emit red light, the second blue pixel Pb2 may emit blue light, and the second green pixel Pg2 may emit green light.

In one or more embodiments, the size (or area) of the second blue pixel Pb2 may be larger than the size (or area) of the second red pixel Pr2 and the size (or area) of the second green pixel Pg2. The size (or area) of the second red pixel Pr2 may be greater than or equal to the size (or area) of the second green pixel Pg2.

The second display area DA2 may include a circuit area PCA and a transmission area TA. In one or more embodiments, the auxiliary light-emitting diodes EDa of the auxiliary pixels Pa may be disposed in the circuit area PCA. In one or more embodiments, some of the auxiliary light-emitting diodes EDa of the auxiliary pixels Pa may be disposed in the circuit area PCA, and the remaining auxiliary light-emitting diodes EDa may be disposed in the transmission area TA.

The auxiliary pixels Pa disposed in the second display area DA2 may be arranged in a PENTILE® arrangement. For example, among the vertices of a virtual square VS with the center point of the second green pixel Pg2 as the center point of the square, a second blue pixel Pb2 may be disposed at the first and third vertices that face each other, and a second red pixel Pr2 may be disposed at the remaining vertices, the second and fourth vertices. Here, the virtual square VS may be changed into various shapes such as a rectangle, a rhombus, and a square.

Although FIGS. 5 and 6 illustrate that the auxiliary pixels Pa and the main pixels Pm are disposed in the same pixel arrangement, the present disclosure is not limited thereto. For example, the auxiliary pixels Pa may be disposed in various configurations such as a stripe arrangement, a mosaic arrangement, and a delta arrangement.

In one or more embodiments, the auxiliary pixels Pa may have a circular shape in a plan view. In another embodiment, the auxiliary pixels Pa may have various shapes in a plan view, such as a polygonal shape, an elliptical shape, etc.

Because the second display area DA2 includes the transmission area TA in which auxiliary pixel circuits PCa are not disposed, the number of auxiliary pixels Pa per unit area of the second display area DA2 may be smaller than the number of main pixels Pm per unit area of the first display area DA1. For example, the number of auxiliary pixels Pa per unit area of the second display area DA2 may be about ½, about ⅓, about ¼, about ⅛, or about 1/16 of the number of main pixels Pm per unit area of the first display area DA1. Therefore, in order to reduce the difference in luminance between the second display area DA2 and the first display area DA1, the luminance of the auxiliary pixel Pa may be greater than the luminance of the main pixel Pm.

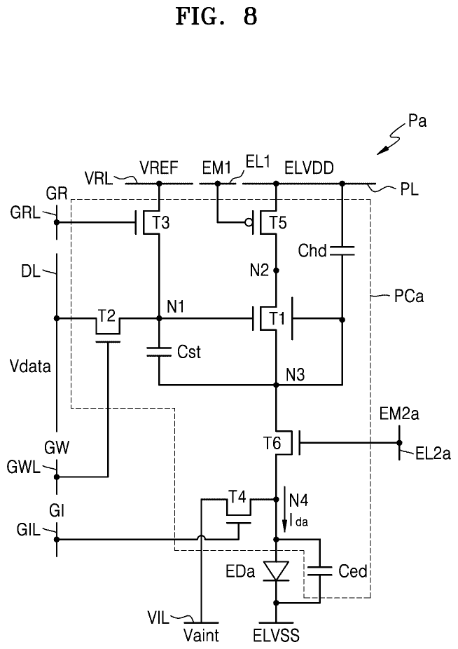

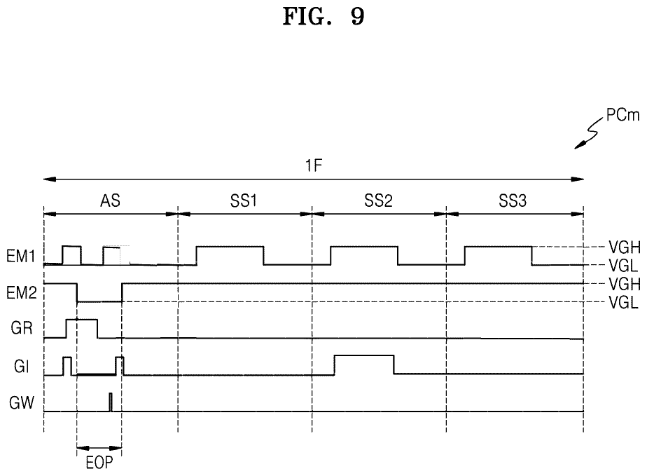

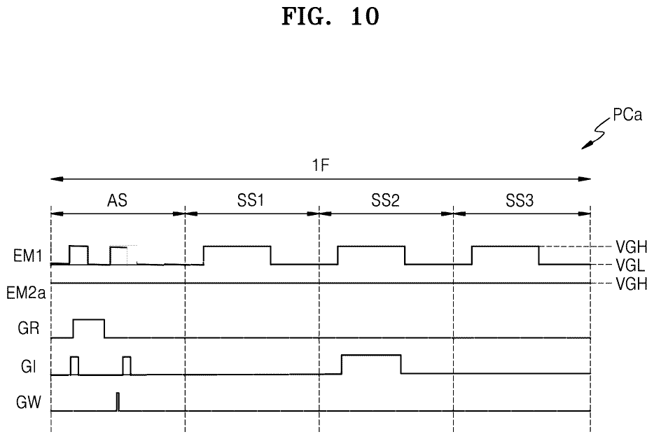

FIG. 7 is an equivalent circuit diagram of a main pixel Pm according to one or more embodiments, and FIG. 8 is an equivalent circuit diagram of an auxiliary pixel Pa according to one or more embodiments. FIG. 9 is a diagram schematically showing signals supplied to the main pixel Pm of FIG. 7, and FIG. 10 is a diagram schematically showing signals supplied to the auxiliary pixel Pa of FIG. 8.

Referring to FIG. 7, main pixel Pm may include a main light-emitting diode EDm and a main pixel circuit PCm electrically connected to the main light-emitting diode EDm.

The main pixel circuit PCm may be electrically connected to a first gate line GWL transmitting a first gate signal GW, a second gate line GRL transmitting a second gate signal GR, a third gate line GIL transmitting a third gate signal GI, a first emission control line EL1 transmitting a first emission control signal EM1, a second emission control line EL2 transmitting a second emission control signal EM2, and a data line DL transmitting a data voltage Vdata.

The first gate signal GW and the first gate line GWL may correspond to the scan signal SS and the scan line SL respectively, described with reference to FIG. 1. Similarly, the first emission control signal EM1 and the second emission control signal EM2 may correspond to the first emission control signal ES1 (see FIG. 1) and the second emission control signal ES2 (see FIG. 1), respectively, and the data voltage Vdata may correspond to the data signal DATA (see FIG. 1).

Additionally, the main pixel circuit PCm may be electrically connected to a driving voltage line PL that transmits a first driving voltage ELVDD, a reference voltage line VRL that transmits a reference voltage VREF, and an initialization voltage line VIL that transmits an initialization voltage Vaint.

The voltage level of the first driving voltage ELVDD may be higher than the voltage level of the second driving voltage ELVSS. The voltage level of the reference voltage VREF may be lower than the voltage level of the first driving voltage ELVDD. The voltage level of the initialization voltage Vaint may be equal to or higher than the voltage level of the second driving voltage ELVSS.

The main pixel circuit PCm may include first to sixth transistors T1, T2, T3, T4, T5, and T6, a first capacitor Cst, a second capacitor Chd, and a third capacitor Ced. The first transistor T1 (e.g., the driving transistor) may be an N-type transistor. At least one of the second to sixth transistors T2, T3, T4, T5, and T6 may be an N-type transistor. In one or more embodiments, the fifth transistor T5 (e.g., the first emission control transistor) may be a P-type transistor. In one or more embodiments, the fifth transistor T5 and the sixth transistor T6 (e.g., the second emission control transistor) may be P-type transistors. In one or more embodiments, the first to sixth transistors T1, T2, T3, T4, T5, and T6 may all be N-type transistors. In one or more embodiments, the N-type transistor may be an oxide-based thin film transistor including a metal oxide semiconductor layer, and the P-type transistor may be a silicon-based thin film transistor including a silicon semiconductor layer.

The first transistor T1 is a driving transistor that outputs a driving current corresponding to the data voltage Vdata, and the second to sixth transistors T2, T3, T4, T5, and T6 may be switching transistors that are turned on or off according to corresponding gate signals. Each of the first terminal (e.g., first electrode) and the second terminal (e.g., second electrode) of the first to sixth transistors T1, T2, T3, T4, T5, and T6 may be a source or a drain. For example, the first terminal may be the source and the second terminal may be the drain, or the first terminal may be the drain and the second terminal may be the source.

The node connected to a first gate of the first transistor T1 may be defined as a first node N1, the node connected to a first terminal of the first transistor T1 may be defined as a second node N2, and the node connected to a second terminal of the first transistor T1 may be defined as a third node N3. The node connected to the first electrode (e.g., pixel electrode) of the main light-emitting diode EDm may be defined as the fourth node N4.

The first transistor T1 may be electrically connected between the driving voltage line PL and the main light-emitting diode EDm. The first gate of the first transistor T1 may be electrically connected to the first node N1, the first terminal of the first transistor T1 may be electrically connected to the second node N2, and the second terminal of the first transistor T1 may be electrically connected to the third node N3. The first transistor T1 may control the driving current flowing to the main light-emitting diode EDm based on the data voltage Vdata, according to the switching operation of the second transistor T2.

The second transistor T2 is a data writing transistor and may be electrically connected between the data line DL and the first transistor T1. The second transistor T2 may include a gate electrically connected to the first gate line GWL, a first terminal electrically connected to the data line DL, and a second terminal electrically connected to the first node N1. The second transistor T2 may be turned on by the first gate signal GW transmitted via the first gate line GWL to electrically connect the data line DL and the first node N1, and may transmit the data voltage Vdata from the data line DL to the first node N1.

The third transistor T3 is a first initialization transistor and may be electrically connected between the first transistor T1 and the reference voltage line VRL. The third transistor T3 may include a gate electrically connected to the second gate line GRL, a first terminal electrically connected to the reference voltage line VRL, and a second terminal electrically connected to the first node N1. The third transistor T3 may be turned on by the second gate signal GR transmitted via the second gate line GRL and may transmit the reference voltage VREF from the reference voltage line VRL to the first node N1.

The fourth transistor T4 is a second initialization transistor and may be electrically connected between the first transistor T1 and the initialization voltage line VIL. The fourth transistor T4 may include a gate electrically connected to a third gate line GIL, a first terminal electrically connected to an initialization voltage line VIL, and a second terminal electrically connected to a fourth node N4. The fourth transistor T4 may be turned on by the third gate signal GI transmitted via the third gate line GIL and may transmit the initialization voltage Vaint from the initialization voltage line VIL to the fourth node N4.

The fifth transistor T5 is the first emission control transistor and may be electrically connected between the driving voltage line PL and the first transistor T1. The fifth transistor T5 may include a gate electrically connected to the first emission control line EL1, a first terminal electrically connected to the driving voltage line PL, and a second terminal electrically connected to the second node N2. The fifth transistor T5 may be turned on or turned off by the first emission control signal EM1 transmitted via the first emission control line EL1.

The sixth transistor T6 is the second emission control transistor and may be electrically connected between the first transistor T1 and the main light-emitting diode EDm. The sixth transistor T6 may include a gate electrically connected to the second emission control line EL2, a first terminal electrically connected to the third node N3, and a second terminal electrically connected to the fourth node N4. The sixth transistor T6 may be turned on or turned off by the second emission control signal EM2 transmitted via the second emission control line EL2.

The first capacitor Cst may be electrically connected between the first gate of the first transistor T1 and the second terminal of the first transistor T1. A first electrode of the first capacitor Cst may be electrically connected to the first node N1, and a second electrode of the first capacitor Cst may be electrically connected to the third node N3. The first capacitor Cst is a storage capacitor and may store a charge corresponding to the threshold voltage of the first transistor T1 and the data voltage Vdata.

The second capacitor Chd may be electrically connected between the driving voltage line PL and the second terminal of the first transistor T1. A first electrode of the second capacitor Chd may be electrically connected to the driving voltage line PL, and a second electrode of the second capacitor Chd may be electrically connected to the third node N3.

The third capacitor Ced may be electrically connected between the fourth node N4 and an auxiliary voltage line or the opposite electrode of the main light-emitting diode EDm, both of which are supplied with the second driving voltage ELVSS.

The capacitance of each of the first capacitor Cst, the second capacitor Chd, and the third capacitor Ced may be formed differently depending on the color of light emitted by the main pixel Pm.

The main light-emitting diode EDm may be electrically connected to the first transistor T1 via the sixth transistor T6. The main light-emitting diode EDm may include a pixel electrode (e.g., anode) electrically connected to a fourth node N4 and an opposite electrode (e.g., cathode) facing the pixel electrode, and the opposite electrode may receive the second driving voltage ELVSS. The opposite electrode may be a common electrode common to a plurality of main pixels Pm.

Referring to FIG. 8, the auxiliary pixel Pa may include an auxiliary light-emitting diode EDa and an auxiliary pixel circuit PCa electrically connected to the auxiliary light-emitting diode EDa.

The auxiliary pixel circuit PCa may be electrically connected to a first gate line GWL transmitting a first gate signal GW, a second gate line GRL transmitting a second gate signal GR, a third gate line GIL transmitting a third gate signal GI, a first emission control line EL1 transmitting a first emission control signal EM1, a third emission control line EL2a transmitting a third emission control signal EM2a, and a data line DL transmitting a data voltage Vdata.

Additionally, the auxiliary pixel circuit PCa may be electrically connected to a driving voltage line PL that transmits a first driving voltage ELVDD, a reference voltage line VRL that transmits a reference voltage VREF, and an initialization voltage line VIL that transmits an initialization voltage Vaint.

The auxiliary pixel circuit PCa may include first to sixth transistors T1, T2, T3, T4, T5, and T6, a first capacitor Cst, a second capacitor Chd, and a third capacitor Ced. The first to fifth transistors T1, T2, T3, T4, and T5, the first capacitor Cst, the second capacitor Chd, and the third capacitor Ced of the auxiliary pixel circuit PCa may correspond to the first to fifth transistors T1, T2, T3, T4, and T5, the first capacitor Cst, the second capacitor Chd, and the third capacitor Ced of the main pixel circuit PCm. Hereinafter, the description of the first to fifth transistors T1, T2, T3, T4, and T5, the first capacitor Cst, the second capacitor Chd, and the third capacitor Ced of the main pixel circuit PCm applies, mutatis mutandis, to the description of the first to fifth transistors T1, T2, T3, T4, and T5, the first capacitor Cst, the second capacitor Chd, and the third capacitor Ced of the auxiliary pixel circuit PCa.

The sixth transistor T6 of the auxiliary pixel circuit PCa is a second emission control transistor and may be electrically connected between the first transistor T1 and the auxiliary light-emitting diode EDa. The sixth transistor T6 may include a gate electrically connected to the third emission control line EL2a, a first terminal electrically connected to the third node N3, and a second terminal electrically connected to the fourth node N4. The sixth transistor T6 of the auxiliary pixel circuit PCa may be maintained in a turn-on state according to the third emission control signal EM2a transmitted via the third emission control line EL2a.

Referring collectively to FIGS. 7 and 9, the main pixel Pm may be driven during one frame 1F including one first scan period AS and at least one second scan period. FIG. 9 illustrates by way of example that a frame 1F includes one first scan period AS and three second scan periods SS1, SS2 and SS3.

Each of the first gate signal GW, the second gate signal GR, the third gate signal GI, the first emission control signal EM1, and the second emission control signal EM2 may have a high-level voltage VGH (e.g., a first-level voltage) for some period of a frame 1F and a low-level voltage VGL (e.g., a second-level voltage) for the remaining period of the frame 1F. Here, the high-level voltage VGH may turn on the N-type transistor and turn off the P-type transistor. The low-level voltage VGL may turn off the N-type transistor and turn on the P-type transistor.

Hereinafter, the on voltage refers to a high-level voltage VGH when a transistor receiving a gate control signal is an N-type transistor, and to a low-level voltage VGL when the transistor is a P-type transistor. Hereinafter, the off voltage refers to a low-level voltage VGL when a transistor receiving a gate control signal is an N-type transistor, and to a high-level voltage VGH when the transistor is a P-type transistor.

The first scan period AS may include a non-emission period in which the main pixel Pm does not emit light and an emission period in which the main pixel Pm emits light. The non-emission period may include a first initialization period, a compensation period, a data writing period, and a second initialization period.

The first initialization period may be a period in which the third gate signal GI having the on voltage is supplied to the third gate line GIL, and the fourth transistor T4 may be turned on by the third gate signal GI. During the first initialization period, the first gate signal GW, and the first emission control signal EM1 may be supplied as the off voltage. By the turned-on fourth transistor T4, the fourth node N4 (i.e., the pixel electrode of the main light-emitting diode EDm) may be initialized to the initialization voltage Vaint.

The compensation period may be a period in which the second gate signal GR having the on voltage is supplied to the second gate line GRL, and the third transistor T3 may be turned on by the second gate signal GR. During the compensation period, the first emission control signal EM1 having the on voltage may be supplied to the first emission control line EL1, and the second emission control signal EM2 having the off voltage may be supplied to the second emission control line EL2. The first gate signal GW may be supplied as the off voltage. The on-voltage period of the third gate signal GI and the on-voltage period of the second gate signal GR may partially overlap. The fifth transistor T5 may be turned on by the first emission control signal EM1 having the on voltage, and the sixth transistor T6 may be turned off by the second emission control signal EM2 having the off voltage.

Accordingly, the reference voltage VREF is supplied to the first node N1, and the first driving voltage ELVDD is supplied to the first terminal of the first transistor T1, so that the first transistor T1 may be turned on. When the voltage of the second terminal of the first transistor T1 drops to the difference (VREF-Vth) between the reference voltage VREF and the threshold voltage (Vth) of the first transistor T1, the first transistor T1 may be turned off. Charge corresponding to the threshold voltage of the first transistor T1 may be stored in the first capacitor Cst, so that the threshold voltage of the first transistor T1 may be compensated.

The data writing period may be a period in which the first gate signal GW having the on voltage is supplied to the first gate line GWL, and the second transistor T2 may be turned on by the first gate signal GW. During the data writing period, the first emission control signal EM1, the second emission control signal EM2, the second gate signal GR, and the third gate signal GI may be supplied as the off voltage.

Through the turned-on second transistor T2, the data voltage Vdata may be transmitted from the data line DL to the first gate of the first transistor T1. Accordingly, the voltage of the first node N1 may be changed to a voltage corresponding to the data voltage Vdata. The voltage of the third node N3 may be changed in response to the voltage change of the first node N1.

The second initialization period may be a period in which the third gate signal GI having the on voltage is supplied to the third gate line GIL, and the fourth transistor T4 may be turned on by the third gate signal GI. The first gate signal GW, the second gate signal GR, the first emission control signal EM1, and the second emission control signal EM2 may be supplied as the off voltage. The fourth node N4 (i.e., the pixel electrode of the main light-emitting diode EDm) may be initialized to the initialization voltage Vaint by the turned-on fourth transistor T4. By initializing the fourth node N4 between the data writing period and emission period, the luminance change of the main light-emitting diode EDm during low gray level (e.g., grayscale value) display may be reduced or minimized, thereby further improving the image quality.

The non-emission period may include a second emission control signal off-period EOP in which the second emission control signal EM2 is supplied as the off voltage. The second emission control signal off-period EOP may overlap with the compensation period, the data writing period, and the second initialization period. Because the sixth transistor T6 is turned off during the second emission control signal off-period EOP, the voltage of the third node N3 may change according to the capacity ratio of the first capacitor Cst and the second capacitor Chd, and may not be affected by the capacity of the third capacitor Ced.

The emission period is a period during which the first emission control signal EM1 having the on voltage is supplied to the first emission control line EL1 and the second emission control signal EM2 having the on voltage is supplied to the second emission control line EL2. The fifth transistor T5 and the sixth transistor T6 may be turned on by the first emission control signal EM1 and the second emission control signal EM2. The first gate signal GW, the second gate signal GR, and the third gate signal GI may be supplied as the off voltage.

A first driving voltage ELVDD may be supplied to the first terminal of the first transistor T1 by the turned-on fifth transistor T5. The first transistor T1 may output a main driving current lam corresponding to the data voltage Vdata stored in the first capacitor Cst. The main driving current lam follows Expression 1 below.

$${I}_{d m} ∝ {( \frac{{C}_{h d}}{{C}_{s t} + {C}_{h d}} ( Vdata - VREF ) )}^{2} \qquad Expression 1$$

The main driving current lam may flow to the main light-emitting diode EDm through the sixth transistor T6 turned on by the second emission control signal EM2, and the main light-emitting diode EDm may emit light with a luminance corresponding to the main driving current Idm.

As illustrated in FIG. 9, the second scan periods SS1, SS2, and SS3 may include a non-emission period in which the first emission control signal EM1 having the off voltage is supplied to the first emission control line EL1 and a emission period in which the first emission control signal EM1 having the on voltage is supplied to the first emission control line EL1. During the second scan periods SS1, SS2, and SS3, the second emission control signal EM2 may be supplied as an on voltage.

The second scan periods SS1, SS2, and SS3 may not include the first initialization period, compensation period, data writing period, and second initialization period. The second scan period SS2 may include a third initialization period in which a third gate signal GI having the on voltage is supplied to the third gate line GIL. During the third initialization period, the first gate signal GW, the second gate signal GR, and the first emission control signal EM1 may be supplied as the off voltage, and the second emission control signal EM2 may be supplied as the on voltage. The fourth transistor T4 may be turned on by the third gate signal GI, and the pixel electrode of the main light-emitting diode EDm may be initialized to the initialization voltage Vaint by the turned-on fourth transistor T4. Accordingly, even when one frame 1F may include a plurality of second scan periods SS1, SS2, and SS3, the luminance deviation according to the driving frequency may be reduced or minimized.

During the emission period of each of the second scan periods SS1, SS2, and SS3, the first driving voltage ELVDD may be supplied to the first terminal of the first transistor T1 by the fifth transistor T5 turned on by the first emission control signal EM1. The first transistor T1 may output a main driving current lam corresponding to the data voltage Vdata stored in the first capacitor Cst. The main driving current ldm may flow to the main light-emitting diode EDm through the sixth transistor T6 turned on by the second emission control signal EM2, and the main light-emitting diode EDm may emit light with a luminance corresponding to the main driving current ldm. The data voltage Vdata stored in the first capacitor Cst during the second scan periods SS1, SS2, and SS3 may represent the data voltage Vdata supplied to the main pixel Pm during the data writing period of the first scan period AS.

Referring collectively to FIGS. 8 and 10, the auxiliary pixel Pa may be driven during one frame 1F including one first scan period AS and at least one second scan period. FIG. 10 illustrates by way of example that a frame 1F includes one first scan period AS and three second scan periods SS1, SS2 and SS3.

The first scan period AS may include a non-emission period in which the auxiliary pixel Pa does not emit light and an emission period in which the auxiliary pixel Pa emits light. The non-emission period may include a first initialization period, a compensation period, a data writing period, and a second initialization period.

The first initialization period may be a period in which the third gate signal GI having the on voltage is supplied to the third gate line GIL, and the fourth transistor T4 may be turned on by the third gate signal GI. During the first initialization period, the first gate signal GW, and the first emission control signal EM1 may be supplied as the off voltage, and the third emission control signal EM2a may be supplied as the on voltage. The third node N3 and the fourth node N4 (i.e., the pixel electrode of the auxiliary light-emitting diode EDa) may be initialized to the initialization voltage Vaint by the turned-on fourth transistor T4 and sixth transistor T6.

The compensation period may be a period in which the second gate signal GR having the on voltage is supplied to the second gate line GRL, and the third transistor T3 may be turned on by the second gate signal GR. During the compensation period, the first emission control signal EM1 and the third emission control signal EM2a may be supplied as the on voltage, and the first gate signal GW may be supplied as the off voltage. The on-voltage period of the third gate signal GI and the on-voltage period of the second gate signal GR may partially overlap. The fifth transistor T5 and the sixth transistor T6 may be turned on by the first emission control signal EM1 and the third emission control signal EM2a.

The data writing period may be a period in which the first gate signal GW having the on voltage is supplied to the first gate line GWL, and the second transistor T2 may be turned on by the first gate signal GW. During the data writing period, the first emission control signal EM1, the second gate signal GR, and the third gate signal GI may be supplied as the off voltage, and the third emission control signal EM2a may be supplied as the on voltage.

Through the turned-on second transistor T2, the data voltage Vdata may be transmitted from the data line DL to the first gate of the first transistor T1. Accordingly, the voltage of the first node N1 may be changed to a voltage corresponding to the data voltage Vdata. The voltage of the third node N3 may be changed in response to the voltage change of the first node N1.

The second initialization period may be a period in which the third gate signal GI having the on voltage is supplied to the third gate line GIL, and the fourth transistor T4 may be turned on by the third gate signal GI. During the second initialization period, the first gate signal GW, the second gate signal GR, and the first emission control signal EM1 may be supplied as the off voltage, and the third emission control signal EM2a may be supplied as the on voltage. The third node N3 and the fourth node N4 may be initialized to the initialization voltage Vaint by the turned-on fourth transistor T4 and sixth transistor T6. By initializing the fourth node N4 between the data writing period and emission period, the luminance change of the auxiliary light-emitting diode EDa during low gray level (e.g., grayscale value) display may be reduced or minimized, thereby further improving the image quality.

During one frame 1F, the third emission control signal EM2a may be supplied as the on voltage to the auxiliary pixel Pa. Because the sixth transistor T6 is maintained in a turn-on state during the non-emission period, the voltage of the third node N3 before the emission period may change according to the capacity ratio of the first capacitor Cst, the second capacitor Chd, and the third capacitor Ced.

The emission period is a period during which the first emission control signal EM1 having the on voltage is supplied to the first emission control line EL1 and the third emission control signal EM2a having the on voltage is supplied to the third emission control line EL2a. The fifth transistor T5 and the sixth transistor T6 may be turned on by the first emission control signal EM1 and the third emission control signal EM2a. The first gate signal GW, the second gate signal GR, and the third gate signal GI may be supplied as the off voltage.

The first driving voltage ELVDD may be supplied to the first terminal of the first transistor T1 by the turned-on fifth transistor T5. The first transistor T1 may output an auxiliary driving current Ida corresponding to the data voltage Vdata stored in the first capacitor Cst. The auxiliary driving current Ida follows Expression 2 below.

$${I}_{d a} ∝ {( \frac{( {C}_{h d} + {C}_{e d} )}{{C}_{s t} + ( {C}_{h d} + {C}_{e d} )} ( Vdata - VREF ) )}^{2} \qquad Expression 2$$

The auxiliary driving current Ida may flow to the auxiliary light-emitting diode EDa through the sixth transistor T6 turned on by the third emission control signal EM2a, and the auxiliary light-emitting diode EDa may emit light with a luminance corresponding to the auxiliary driving current Ida.

As illustrated in FIG. 10, the second scan periods SS1, SS2, and SS3 may include a non-emission period in which the first emission control signal EM1 having the off voltage is supplied to the first emission control line EL1 and a emission period in which the first emission control signal EM1 having the on voltage is supplied to the first emission control line EL1. During the second scan periods SS1, SS2 and SS3, the third emission control signal EM2a having on voltage may be supplied to the third emission control line EL2a.

The second scan periods SS1, SS2, and SS3 may not include the first initialization period, compensation period, data writing period, and second initialization period. The second scan period SS2 may include a third initialization period in which a third gate signal GI having the on voltage is supplied to the third gate line GIL.

During the emission period of each of the second scan periods SS1, SS2, and SS3, the first driving voltage ELVDD may be supplied to the first terminal of the first transistor T1 by the fifth transistor T5 turned on by the first emission control signal EM1. The first transistor T1 may output the auxiliary driving current Ida corresponding to the data voltage Vdata stored in the first capacitor Cst. The auxiliary driving current Ida may flow to the auxiliary light-emitting diode EDa through the sixth transistor T6 turned on by the third emission control signal EM2a, and the auxiliary light-emitting diode EDa may emit light with a luminance corresponding to the auxiliary driving current Ida. The data voltage Vdata stored in the first capacitor Cst during the second scan periods SS1, SS2, and SS3 may represent the data voltage Vdata supplied to the auxiliary pixel Pa during the data writing period of the first scan period AS.

The sixth transistor T6 of the main pixel circuit PCm may be turned off during the second emission control signal off-period EOP in which the second emission control signal EM2 is supplied as the off voltage, and turned on during a period other than the second emission control signal off-period EOP. On the other hand, the sixth transistor T6 of the auxiliary pixel circuit PCa may be maintained in a turn-on state for one frame 1F because the third emission control signal EM2a is supplied as the on voltage for one frame 1F.

As described above, the main driving current lam output by the main pixel circuit PCm is based on the capacity of the first capacitor Cst and the capacity of the second capacitor Chd, whereas the auxiliary driving current Ida output by the auxiliary pixel circuit PCa is based on the capacity of the first capacitor Cst, and the sum (Chd+Ced) of the capacity of the second capacitor Chd and the capacity of the third capacitor Ced. Therefore, the main driving current lam may be smaller than the auxiliary driving current Ida. Accordingly, the luminance of the auxiliary pixel Pa may be greater than that of the main pixel Pm, such that the resulting luminance difference compensates for the difference in the number of pixels per unit area between the second display area DA2 and the first display area DA1.

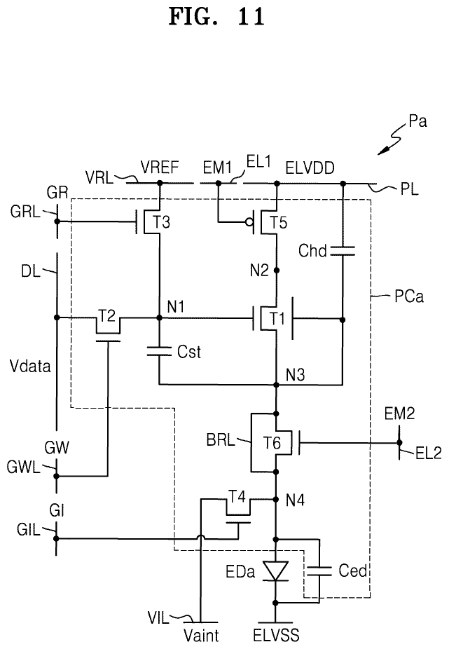

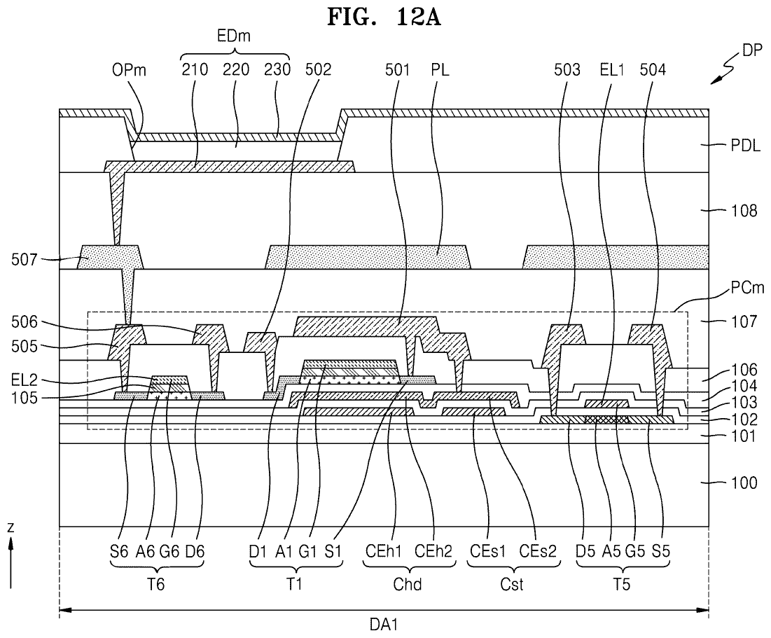

FIG. 11 is an equivalent circuit diagram of an auxiliary pixel Pa according to one or more embodiments.

Referring to FIG. 11, the auxiliary pixel Pa may include an auxiliary light-emitting diode EDa and an auxiliary pixel circuit PCa electrically connected to the auxiliary light-emitting diode EDa.

The auxiliary pixel circuit PCa may be electrically connected to a first gate line GWL transmitting a first gate signal GW, a second gate line GRL transmitting a second gate signal GR, a third gate line GIL transmitting a third gate signal GI, a first emission control line EL1 transmitting a first emission control signal EM1, a second emission control line EL2 transmitting a second emission control signal EM2, and a data line DL transmitting a data voltage Vdata.

Additionally, the auxiliary pixel circuit PCa may be electrically connected to a driving voltage line PL that transmits a first driving voltage ELVDD, a reference voltage line VRL that transmits a reference voltage VREF, and an initialization voltage line VIL that transmits an initialization voltage Vaint.

The auxiliary pixel circuit PCa may include first to sixth transistors T1, T2, T3, T4, T5, and T6, a first capacitor Cst, a second capacitor Chd, and a third capacitor Ced. The auxiliary pixel circuit PCa of FIG. 11 has a similar configuration to the auxiliary pixel circuit PCa of FIG. 8, but differs in that the gate of the sixth transistor T6 is electrically connected to the second emission control line EL2, and the auxiliary pixel circuit PCa further includes a conductive line BRL that electrically connects the third node N3 and the fourth node N4. Hereinafter, the description of similar components is omitted, and the description will focus on the differences.

The sixth transistor T6 of the auxiliary pixel circuit PCa is a second emission control transistor and may be electrically connected between the first transistor T1 and the auxiliary light-emitting diode EDa. The sixth transistor T6 may include a gate electrically connected to the second emission control line EL2, a first terminal electrically connected to the third node N3, and a second terminal electrically connected to the fourth node N4. The sixth transistor T6 of the auxiliary pixel circuit PCa may be turned on or turned off by the second emission control signal EM2, similarly to the sixth transistor T6 of the main pixel circuit PCm (see FIG. 7).

The conductive line BRL may electrically connect the third node N3 and the fourth node N4. That is, the conductive line BRL may electrically connect the first terminal of the sixth transistor T6 and the second terminal of the sixth transistor T6, or electrically connect the first terminal of the sixth transistor T6 and the pixel electrode of the auxiliary light-emitting diode EDa. Accordingly, even when the sixth transistor T6 is turned off by the second emission control signal EM2 having the off voltage, the third node N3 and the fourth node N4 may be electrically connected through the conductive line BRL. That is, the conductive line BRL may maintain a conductive path through which current flows between the third node N3 and the auxiliary light-emitting diode EDa even when the sixth transistor T6 is turned off. Therefore, the luminance of the auxiliary pixel Pa may be increased without using a separate emission control line and emission control signal to control the sixth transistor T6 of the auxiliary pixel circuit PCa.

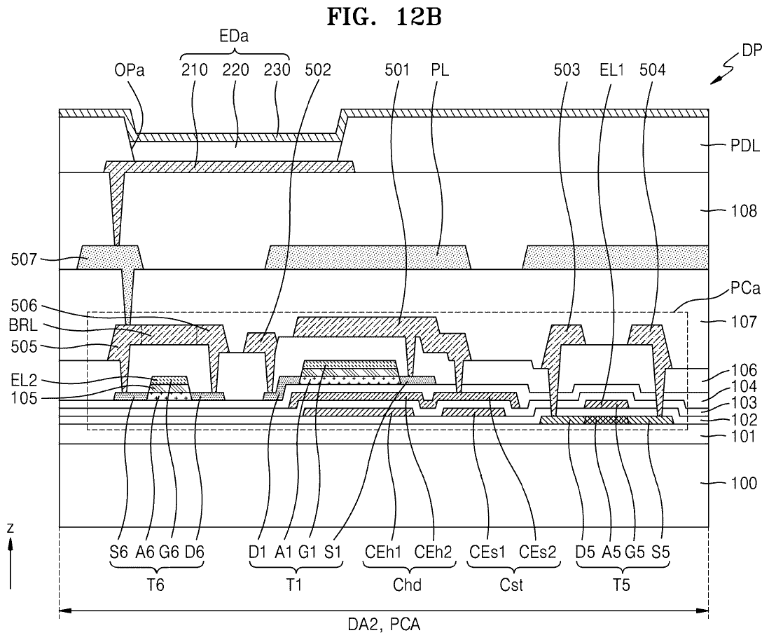

FIG. 12A is a schematic cross-sectional view of a first display area DA1 of a display panel DP according to one or more embodiments, and FIG. 12B is a schematic cross-sectional view of a second display area DA2 of a display panel DP according to one or more embodiments.

Referring collectively to FIGS. 12A and 12B, the display panel DP may include a substrate 100 including a first display area DA1 and a second display area DA2, a main light-emitting diode EDm disposed in the first display area DA1 and electrically connected to a main pixel circuit PCm, and an auxiliary light-emitting diode EDa disposed in a circuit area PCA of the second display area DA2 and electrically connected to an auxiliary pixel circuit PCa.

The substrate 100 may include various materials such as glass, metal, or polymer resin. The polymer resin may include polyethersulfone, polyacrylate, polyether imide, polyethylene naphthalate, polyethylene terephthalate, polyphenylene sulfide, polyarylate, polyimide, polycarbonate, and/or cellulose acetate propionate. The substrate 100 may be provided with a multi-layered structure in which a polymer resin and an inorganic insulating material are laminated. For example, the substrate 100 may have a multi-layered structure in which a base layer including a polymer resin and a barrier layer including an inorganic insulating material are alternately laminated.

A buffer layer 101 may be disposed on the substrate 100. The buffer layer 101 may reduce or block the penetration of moisture and/or the like from under the substrate 100. The buffer layer 101 may include an inorganic insulating material such as silicon oxide, silicon oxynitride, and/or silicon nitride, and may be provided as a single layer or multi-layered structure including the materials described above.

A main pixel circuit PCm and an auxiliary pixel circuit PCa may be disposed on a buffer layer 101. The main pixel circuit PCm and the auxiliary pixel circuit PCa may each include a first transistor T1, a fifth transistor T5, a sixth transistor T6, a first capacitor Cst, and a second capacitor Chd.

The fifth transistor T5 may include a first semiconductor layer and a fifth gate electrode G5 disposed over the first semiconductor layer. In one or more embodiments, the fifth gate electrode G5 may be a part of the first emission control line EL1. The first semiconductor layer may include a fifth channel region A5 overlapping a fifth gate electrode G5 in a plan view (e.g., in a +z direction or in a thickness direction of the substrate 100), and a fifth drain region D5 and a fifth source region S5 disposed at opposite ends of the fifth channel region A5 and doped with impurities. The first semiconductor layer may be a silicon semiconductor layer including a silicon semiconductor material. For example, the first semiconductor layer may include polysilicon.

A first gate insulating layer 102 may be interposed between the first semiconductor layer and the fifth gate electrode G5 and may be disposed on the buffer layer 101. The first gate insulating layer 102 may include an inorganic insulating material such as silicon oxide, silicon oxynitride, and/or silicon nitride, and may be provided as a single layer or multi-layered structure including the materials described above.

A first electrode CEs1 of a first capacitor Cst and a first electrode CEh1 of a second capacitor Chd may be disposed on a first gate insulating layer 102. The fifth gate electrode G5 of the fifth transistor T5, the first electrode CEs1 of the first capacitor Cst, and the first electrode CEh1 of the second capacitor Chd may include a low-resistance conductive material such as molybdenum (Mo), aluminum (Al), copper (Cu), and/or titanium (Ti), and may be provided as a single layer or multi-layered structure including the materials described above.

A first interlayer insulating layer 103 may be disposed to cover the fifth gate electrode G5 of the fifth transistor T5, the first electrode CEs1 of the first capacitor Cst, and the first electrode CEh1 of the second capacitor Chd, and may be disposed on a first gate insulating layer 102. The first interlayer insulating layer 103 may include an inorganic insulating material such as silicon oxide, silicon oxynitride, and/or silicon nitride, and may be provided as a single layer or multi-layered structure including the materials described above.

A second electrode CEs2 of a first capacitor Cst and a second electrode CEh2 of a second capacitor Chd may be disposed on the first interlayer insulating layer 103. The first electrode CEs1 and the second electrode CEs2 of the first capacitor Cst may overlap each other in a plan view (e.g., in a +z direction or in a thickness direction of the substrate 100). The first electrode CEh1 and the second electrode CEh2 of the second capacitor Chd may overlap each other in a plan view (e.g., in a +z direction or in a thickness direction of the substrate 100). The second electrode CEs2 of the first capacitor Cst and the second electrode CEh2 of the second capacitor Chd may be integrally provided. The second electrode CEs2 of the first capacitor Cst and the second electrode CEh2 of the second capacitor Chd may include a low-resistance conductive material such as molybdenum (Mo), aluminum (Al), copper (Cu), and/or titanium (Ti), and may be provided as a single layer or multi-layered structure including the materials described above.

A second interlayer insulating layer 104 may be disposed on the second electrode CEs2 of the first capacitor Cst and the second electrode CEh2 of the second capacitor Chd and may be disposed on the first interlayer insulating layer 103. The second interlayer insulating layer 104 may include an inorganic insulating material such as silicon oxide, silicon oxynitride, and/or silicon nitride, and may be provided as a single layer or multi-layered structure including the materials described above.

The first transistor T1 may include a second semiconductor layer and a first gate electrode G1 disposed over the second semiconductor layer. The second semiconductor layer may include a first channel region A1 overlapping the first gate electrode G1 in a plan view (e.g., in a +z direction or in a thickness direction of the substrate 100), and a first drain region D1 and a first source region S1 disposed at opposite ends of the first channel region A1 and doped with impurities.

The sixth transistor T6 may include a third semiconductor layer and a sixth gate electrode G6 disposed over the third semiconductor layer. In one or more embodiments, the sixth gate electrode G6 may be a part of the second emission control line EL2. The third semiconductor layer may include a sixth channel region A6 overlapping the sixth gate electrode G6 in a plan view (e.g., in a +z direction or in a thickness direction of the substrate 100), and a sixth drain region D6 and a sixth source region S6 disposed at opposite ends of the sixth channel region A6 and doped with impurities.

In one or more embodiments, each of the second semiconductor layer and the third semiconductor layer may be an oxide semiconductor layer including an oxide semiconductor material. The oxide semiconductor material may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), and zinc (Zn). In one or more embodiments, the second semiconductor layer may be an oxide semiconductor layer, and the third semiconductor layer may be a silicon semiconductor layer.

A second gate insulating layer 105 may be interposed between the second semiconductor layer and the first gate electrode G1 and between the third semiconductor layer and the sixth gate electrode G6. The second gate insulating layer 105 may include an inorganic insulating material such as silicon oxide, silicon oxynitride, and/or silicon nitride, and may be provided as a single layer or multi-layered structure including the materials described above. In one or more embodiments, the second gate insulating layer 105 may have a shape corresponding to the first gate electrode G1 and the sixth gate electrode G6.

The first gate electrode G1 of the first transistor T1 and the sixth gate electrode G6 of the sixth transistor T6 may include a low-resistance conductive material such as molybdenum (Mo), aluminum (Al), copper (Cu), and/or titanium (Ti), and may be provided as a single layer or multi-layered structure including the materials described above.

A third interlayer insulating layer 106 may be disposed on the first gate electrode G1 of the first transistor T1 and the sixth gate electrode G6 of the sixth transistor T6 and may be disposed on the second interlayer insulating layer 104. The third interlayer insulating layer 106 may include an inorganic insulating material such as silicon oxide, silicon oxynitride, and/or silicon nitride, and may be provided as a single layer or multi-layered structure including the materials described above.

The first to sixth connecting electrodes 501, 502, 503, 504, 505 and 506 may be disposed on the third interlayer insulating layer 106. A first planarization layer 107 may be disposed on the first to sixth connecting electrodes 501, 502, 503, 504, 505 and 506 and the third interlayer insulating layer 106, and a seventh connecting electrode 507 and a driving voltage line PL may be disposed on the first planarization layer 107. The first planarization layer 107 may include an organic insulating material such as acrylic, Benzocyclobutene (BCB), polyimide, and/or Hexamethyldisiloxane (HMDSO). The first to seventh connecting electrodes 501, 502, 503, 504, 505, 506 and 507, and the driving voltage line PL may include a low-resistance conductive material such as molybdenum (Mo), aluminum (Al), copper (Cu), and/or titanium (Ti), and may be provided as a single layer or multi-layered structure including the materials described above. For example, the first to seventh connecting electrodes 501, 502, 503, 504, 505, 506 and 507 and the driving voltage line PL may have a three-layered structure of titanium layer/aluminum layer/titanium layer.

The first connecting electrode 501 may electrically connect the first source region S1 of the first transistor T1, the second electrode CEs2 of the first capacitor Cst, and the second electrode CEh2 of the second capacitor Chd to form a third node N3 (see FIGS. 7 and 11).

The second connecting electrode 502 may be electrically connected to the first drain region D1 of the first transistor T1. The third connecting electrode 503 may be electrically connected to the fifth drain region D5 of the fifth transistor T5. The second connecting electrode 502 and the third connecting electrode 503 may be electrically connected to each other, to electrically connect the first drain region D1 of the first transistor T1 and the fifth drain region D5 of the fifth transistor T5.

The fourth connecting electrode 504 may be electrically connected to the fifth source region S5 of the fifth transistor T5 and the driving voltage line PL. The fifth connecting electrode 505 may be electrically connected to the sixth source region S6 of the sixth transistor T6, and the seventh connecting electrode 507.

The sixth connecting electrode 506 may be electrically connected to the sixth drain region D6 of the sixth transistor T6. In one or more embodiments, the sixth connecting electrode 506 may be electrically connected to the first connecting electrode 501. In one or more embodiments, the sixth connecting electrode 506 may be omitted, and the first source region S1 of the first transistor T1 and the sixth drain region D6 of the sixth transistor T6 may be connected to each other.

The auxiliary pixel circuit PCa disposed in the second display area DA2 may further include a conductive line BRL. In one or more embodiments, the conductive line BRL may electrically connect the fifth connecting electrode 505 and the sixth connecting electrode 506. Through the conductive line BRL, the sixth source region S6 and the sixth drain region D6 of the sixth transistor T6 may be electrically connected. In one or more embodiments, because the sixth connecting electrode 506 may be electrically connected to the first connecting electrode 501, the conductive line BRL may electrically connect the fifth connecting electrode 505 and the first connecting electrode 501. That is, the conductive line BRL may electrically connect the pixel electrode 210 of the auxiliary light-emitting diode EDa and the first source region S1 of the first transistor T1, and may maintain a conductive path for current flow between the third node N3 (see FIG. 11) and the pixel electrode 210 of the auxiliary light-emitting diode EDa, even when the sixth transistor T6 is turned off.

A second planarization layer 108 may be disposed on the seventh connecting electrode 507, the driving voltage line PL, and the first planarization layer 107. The second planarization layer 108 may include an organic insulating material such as acrylic, Benzocyclobutene (BCB), polyimide, and/or Hexamethyldisiloxane (HMDSO).

The main light-emitting diode EDm and the auxiliary light-emitting diode EDa may be disposed on the second planarization layer 108. The main light-emitting diode EDm may be disposed on the main pixel circuit PCm, and the auxiliary light-emitting diode EDa may be disposed on the auxiliary pixel circuit PCa. Each of the main light-emitting diode EDm and the auxiliary light-emitting diode EDa may include a pixel electrode 210, an emission layer 220, and an opposite electrode 230.

Pixel electrodes 210 may be disposed on the second planarization layer 108. The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), and/or a compound or mixture thereof. The pixel electrode 210 may include a reflective film including the material described above, and a transparent conductive film disposed on or/and below the reflective film. The transparent conductive film may include indium tin oxide (ITO), indium zinc oxide (IZO), zinc oxide (ZnO), indium oxide (In₂O₃), indium gallium oxide (IGO), and/or aluminum zinc oxide (AZO). For example, the pixel electrode 210 may have a three-layered structure of ITO layer/Ag layer/ITO layer.

A pixel defining layer PDL may cover the edge of each of the pixel electrodes 210 and may define openings OPm and OPa that expose the center of each of the pixel electrodes 210. The main pixel opening OPm of the pixel defining layer PDL may overlap the pixel electrode 210 of the main light-emitting diode EDm in a plan view. The main pixel opening OPm may define the emission area of the main light-emitting diode EDm. The auxiliary pixel opening OPa of the pixel defining layer PDL may overlap the pixel electrode 210 of the auxiliary light-emitting diode EDa in a plan view. The auxiliary pixel opening OPa may define the emission area of the auxiliary light-emitting diode EDa. The pixel defining layer PDL may include organic insulating materials such as polyimide, polyamide, acrylic resin, benzocyclobutene, hexamethyldisiloxane (HMDSO), and phenol resin, and may be formed by methods such as spin coating.

The emission layer 220 may be disposed in each of the main pixel opening OPm and the auxiliary pixel opening OPa of the pixel defining layer PDL corresponding to each of the pixel electrodes 210. The emission layer 220 may include a high molecular weight organic material or a low molecular weight organic material that emits light of a certain color. A first functional layer may be disposed between the pixel electrode 210 and the emission layer 220, and a second functional layer may be disposed between the emission layer 220 and the opposite electrode 230. The first functional layer may include a hole transport layer (HTL) and/or a hole injection layer (HIL). The second functional layer may include an electron transport layer (ETL) and/or an electron injection layer (EIL). Unlike the emission layer 220, the first functional layer and/or the second functional layer may be integrally provided on the substrate 100. In other words, the first functional layer and/or the second functional layer may cover the first display area DA1 and the second display area DA2.

The opposite electrode 230 may be disposed on the emission layer 220. The opposite electrode 230 may include a conductive material having a low work function. For example, the opposite electrode 230 may include a transparent layer or semi-transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 230 may further include a layer such as ITO, IZO, ZnO, and/or In₂O₃ on the transparent layer or semi-transparent layer including the material described above. The opposite electrode 230 may be formed integrally to correspond to the main light-emitting diodes EDm disposed in the first display area DA1 and the auxiliary light-emitting diodes EDa disposed in the second display area DA2.

A thin film encapsulation layer 300 (see FIG. 3) may be disposed on the opposite electrode 230. The thin film encapsulation layer 300 may cover the main light-emitting diode EDm and the auxiliary light-emitting diode EDa.

Although FIGS. 12A and 12B illustrate that the fifth transistor T5 is a silicon-based thin film transistor including a silicon semiconductor layer and the sixth transistor T6 is an oxide-based thin film transistor including an oxide semiconductor layer, the present disclosure is not limited thereto.

In one or more embodiments, the fifth transistor T5 may be an oxide-based thin film transistor including an oxide semiconductor layer. In this case, the first semiconductor layer of the fifth transistor T5 may be disposed in the same layer as the second semiconductor layer of the first transistor T1, and the fifth gate electrode G5 of the fifth transistor T5 may be disposed in the same layer as the first gate electrode G1 of the first transistor T1.

In one or more embodiments, the fifth transistor T5 and the sixth transistor T6 may be silicon-based thin film transistors including a silicon semiconductor layer. In this case, the third semiconductor layer of the sixth transistor T6 may be disposed in the same layer as the first semiconductor layer of the fifth transistor T5, and the sixth gate electrode G6 of the sixth transistor T6 may be disposed in the same layer as the fifth gate electrode G5 of the fifth transistor T5.

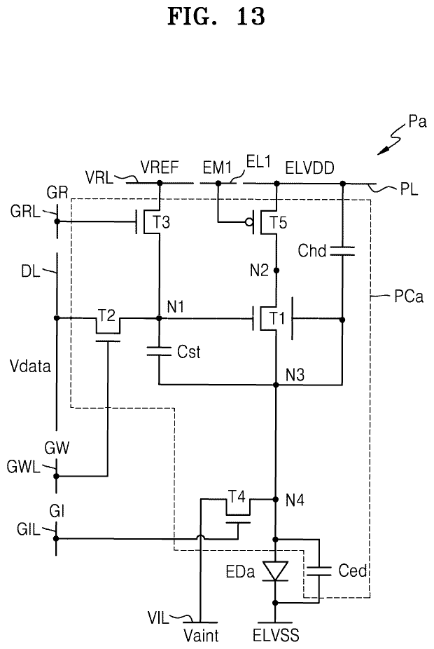

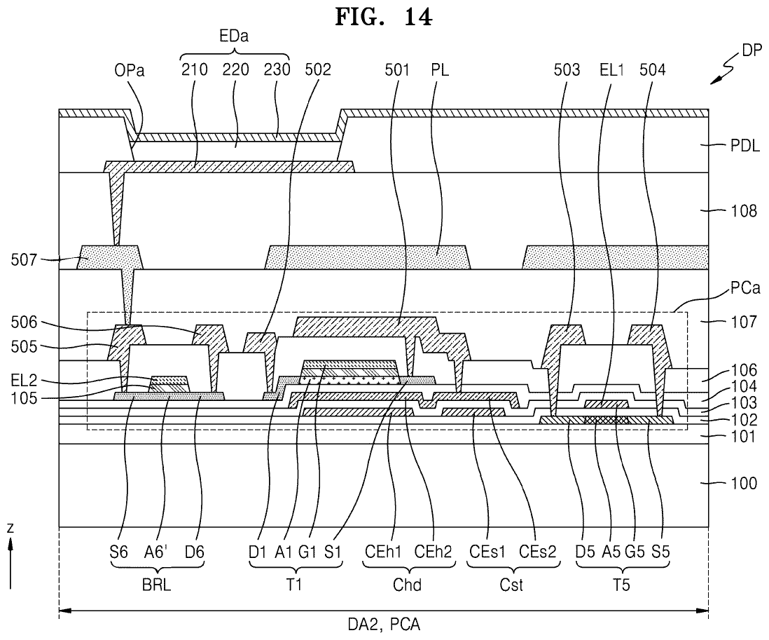

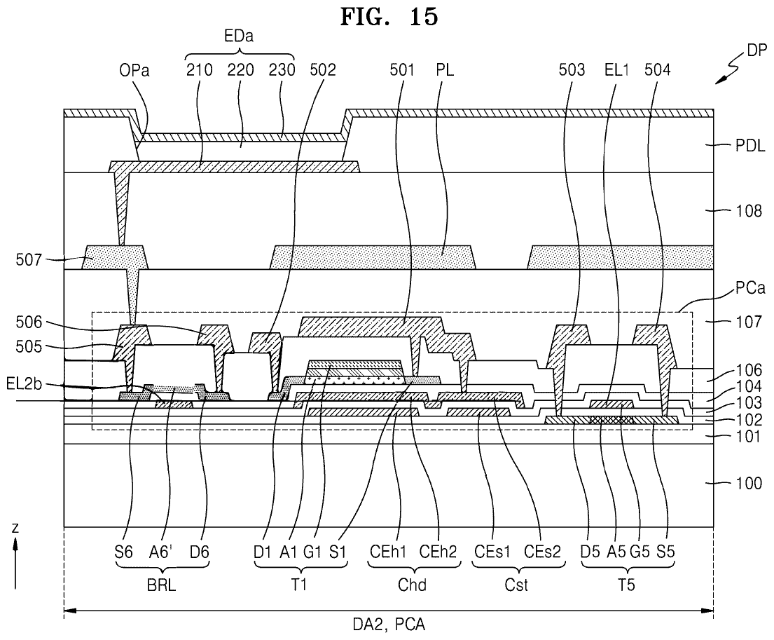

FIG. 13 is an equivalent circuit diagram of an auxiliary pixel Pa according to one or more embodiments. FIGS. 14 and 15 are schematic cross-sectional views, each illustrating a second display area DA2 of a display panel DP according to an embodiment.

Referring to FIG. 13, the auxiliary pixel Pa may include an auxiliary light-emitting diode EDa and an auxiliary pixel circuit PCa electrically connected to the auxiliary light-emitting diode EDa.

The auxiliary pixel circuit PCa may be electrically connected to a first gate line GWL transmitting a first gate signal GW, a second gate line GRL transmitting a second gate signal GR, a third gate line GIL transmitting a third gate signal GI, a first emission control line EL1 transmitting a first emission control signal EM1, and a data line DL transmitting a data voltage Vdata. The second emission control line EL2 (see FIG. 7) may pass through the auxiliary pixel circuit PCa, but may not be electrically connected to the auxiliary pixel circuit PCa. That is, the components of the auxiliary pixel circuit PCa may not be turned on or turned off by the second emission control signal EM2 (see FIG. 7) transmitted by the second emission control line EL2.

The auxiliary pixel circuit PCa may be electrically connected to a driving voltage line PL that transmits a first driving voltage ELVDD, a reference voltage line VRL that transmits a reference voltage VREF, and an initialization voltage line VIL that transmits an initialization voltage Vaint.

The auxiliary pixel circuit PCa may include first to fifth transistors T1, T2, T3, T4, and T5, a first capacitor Cst, a second capacitor Chd, and a third capacitor Ced. The auxiliary pixel circuit PCa of FIG. 13 has a similar configuration to the auxiliary pixel circuit PCa of FIG. 8, but the sixth transistor T6 (see FIG. 8) may be omitted. The third node N3 of the auxiliary pixel circuit PCa may be electrically connected to the fourth node N4 via the conductive line BRL, without passing through a transistor.

For example, as illustrated in FIGS. 14 and 15, the auxiliary pixel circuit PCa may include a fourth semiconductor layer having a shape corresponding to the third semiconductor layer of the sixth transistor T6 (see FIG. 12A) of the main pixel circuit PCm (see FIG. 12A). The fourth semiconductor layer may include a conductive region A6′ corresponding to a sixth channel region A6 (see FIG. 12A) of the sixth transistor T6 of the main pixel circuit PCm, and a sixth drain region D6 and a sixth source region S6 arranged at both ends of the conductive region A6′. The conductive region A6′, the sixth drain region D6, and the sixth source region S6 may be doped with impurities to become conductive. The fourth semiconductor layer may form a conductive line BRL that electrically connects the fifth connecting electrode 505 and the sixth connecting electrode 506.

Referring to FIG. 14, the second emission control line EL2 may cross the fourth semiconductor layer. The second emission control line EL2 may be disposed over the fourth semiconductor layer, similarly to the main pixel circuit PCm (see FIG. 12A). The second emission control line EL2 may overlap the conductive region A6′ in a plan view (e.g., in the +z direction or in the thickness direction of the substrate 100). The conductive region A6′ may be made conductive through a process using a mask. The conductive region A6′ may maintain a conductive path that electrically connects the fifth connecting electrode 505 and the sixth connecting electrode 506 even when the second emission control line EL2 transmits the second emission control signal EM2 (see FIG. 7) having the off voltage.

Referring to FIG. 15, an auxiliary emission control line EL2b may be disposed between the fourth semiconductor layer and the substrate 100. The auxiliary emission control line EL2b may be disposed in the second display area DA2 and may be electrically connected to the second emission control line EL2 of the same row. That is, the second emission control line EL2 may be separated into two parts with the second display area DA2 in between, and the two parts of the second emission control line EL2 may be electrically connected by the auxiliary emission control line EL2b disposed in the second display area DA2, to transmit the second emission control signal EM2 (see FIG. 7) to the main pixels Pm.

When doping an oxide semiconductor layer, the portion overlapped by the gate electrode on the oxide semiconductor layer may be not doped and may constitute a channel region of the transistor. In the main pixel circuit PCm (see FIG. 12A), the second emission control line EL2 may be disposed on the third semiconductor layer, so a portion of the third semiconductor layer overlapping the second emission control line EL2 may not be doped and may constitute the sixth channel region A6 of the sixth transistor T6. In the auxiliary pixel circuit PCa of FIG. 15, the auxiliary emission control line EL2b may be disposed below the fourth semiconductor layer, so the conductive region A6′ may be doped together with the sixth source region S6 and the sixth drain region D6 and may form the conductive line BRL.

The conductive line BRL may electrically connect the pixel electrode 210 of the auxiliary light-emitting diode EDa and the first source region S1 of the first transistor T1 (e.g., because the sixth connecting electrode 506 may be electrically connected to the first connecting electrode 501), and may maintain a conductive path for current flow between the first connecting electrode 501 corresponding to the third node N3 and the pixel electrode 210 of the auxiliary light-emitting diode EDa.

Although FIG. 15 illustrates that the auxiliary emission control line EL2b is disposed in the same layer as the second electrode CEs2 of the first capacitor Cst and the second electrode CEh2 of the second capacitor Chd, the present disclosure is not limited thereto. For example, the auxiliary emission control line EL2b may be disposed in the same layer as the fifth gate electrode G5 of the fifth transistor T5, the first electrode CEs1 of the first capacitor Cst, and the first electrode CEh1 of the second capacitor Chd.

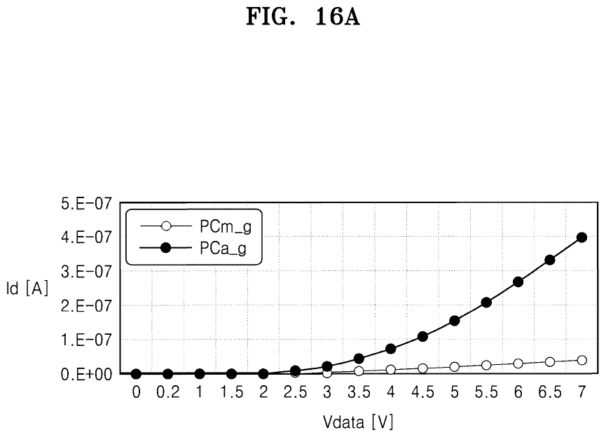

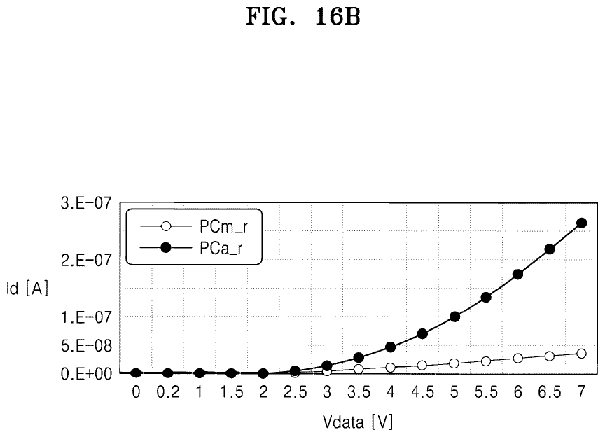

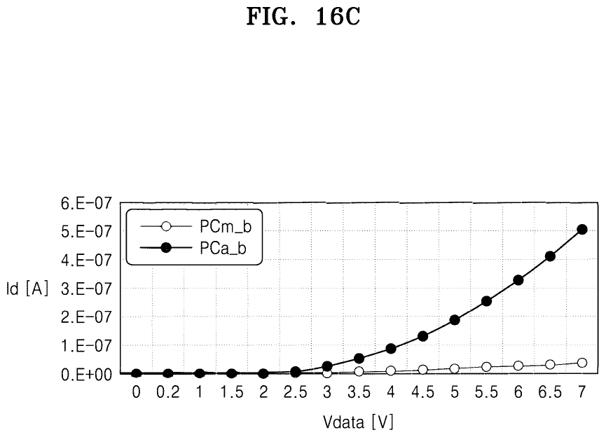

FIGS. 16A, 16B, and 16C are graphs illustrating driving currents of a main pixel circuit and an auxiliary pixel circuit, according to one or more embodiments, with respect to data voltage.

FIG. 16A shows simulation results of the driving current output by the first main pixel circuit PCm_g of the first green pixel Pg1 (see FIG. 5), and the driving current output by the first auxiliary pixel circuit PCa_g of the second green pixel Pg2 (see FIG. 6). FIG. 16B shows simulation results of the driving current output by the second main pixel circuit PCm_r of the first red pixel Pr1 (see FIG. 5), and the driving current output by the second auxiliary pixel circuit PCa_r of the second red pixel Pr2 (see FIG. 6). FIG. 16C shows simulation results of the driving current output by the third main pixel circuit PCm_b of the first blue pixel Pb1 (see FIG. 5), and the driving current output by the third auxiliary pixel circuit PCa_b of the second blue pixel Pb2 (see FIG. 6).

Each of the first main pixel circuit PCm_g, the second main pixel circuit PCm_r, and the third main pixel circuit PCm_b may have a configuration corresponding to the main pixel circuit PCm illustrated in FIG. 7. Each of the first auxiliary pixel circuit PCa_g, the second auxiliary pixel circuit PCa_r, and the third auxiliary pixel circuit PCa_b may have a configuration corresponding to the auxiliary pixel circuit PCa illustrated in FIG. 8. The third emission control signal EM2a (see FIG. 10) may be supplied to the gate of the sixth transistor T6 (see FIG. 8) of each of the first auxiliary pixel circuit PCa_g, the second auxiliary pixel circuit PCa_r, and the third auxiliary pixel circuit PCa_b, so that the sixth transistor T6 may be maintained in a turn-on state for a frame 1F. That is, a conductive path through which current flows may be maintained between the third node N3 (see FIG. 8) and the light-emitting diode in each of the first auxiliary pixel circuit PCa_g, the second auxiliary pixel circuit PCa_r, and the third auxiliary pixel circuit PCa_b.

Referring to FIGS. 16A, 16B, and 16C, in the data voltage Vdata region corresponding to grayscale expression, the first auxiliary pixel circuit PCa_g may output a current about 4 to 10 times greater than that of the first main pixel circuit PCm_g. The second auxiliary pixel circuit PCa_r may output a current about 5 to 7 times greater than that of the second main pixel circuit PCm_r. The third auxiliary pixel circuit PCa_b may output a current about 10 times greater than that of the third main pixel circuit PCm_b.

According to one or more embodiments of the present disclosure, by maintaining the sixth transistor T6 of the auxiliary pixel circuit PCa in a turn-on state or forming a conductive path through which current flows between the third node N3 and the auxiliary light-emitting diode EDa through the conductive line BRL, the driving current output by the auxiliary pixel circuit PCa may be increased. As the driving current output from the auxiliary pixel circuit PCa increases, the luminance of the auxiliary light-emitting diode EDa increases, thereby reducing the luminance difference caused by the difference in the number of pixels per unit area between the first display area DA1 and the second display area DA2.

The display apparatus 1 according to one or more embodiments of the present disclosure may be employed by various electronic devices. An electronic device according to one or more embodiments includes the display apparatus 1 described above, and may further include a module or device having additional functions in addition to the display apparatus 1.

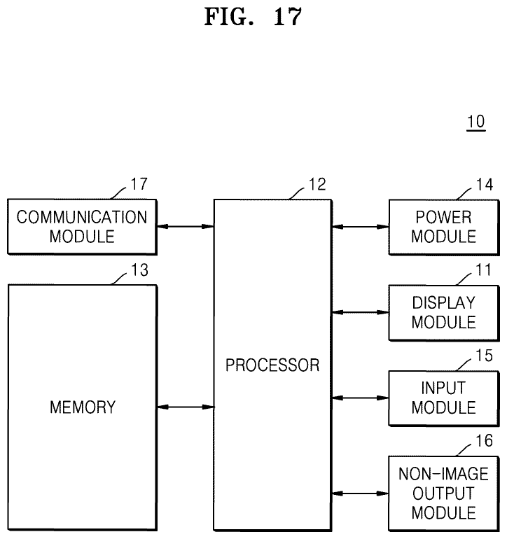

FIG. 17 is a schematic block diagram of an electronic device 10 according to one or more embodiments.

Referring to FIG. 17, an electronic device 10 according to one or more embodiments may include a display module 11, a processor 12, a memory 13, and a power module 14. The electronic device 10 may further include an input module 15, a non-image output module 16, and/or a communication module 17.

An electronic device 10 may output various information in the form of an image through a display module 11. When the processor 12 executes an application stored in the memory 13, the image information provided by the application may be provided to the user through the display module 11. The power module 14 may include a power supply module, such as a power adaptor or a battery device, and a power conversion module configured to convert power supplied from the power supply module and generate power necessary for operations of the electronic device 10. The input module 15 may provide input information to the processor 12 and/or the display module 11. The non-image output module 16 may receive information other than image from the processor 12, such as sound, haptics, and/or light, and provide the information to the user. The communication module 17 may be configured to perform transmission and reception of information between the electronic device 10 and an external device and may include a receiver and/or a transmitter.

The processor 12 may be provided by being divided into two or more processors from a functional or structural perspective. For example, the processor 12 may include a main processor as a first driving chip including a CPU and an auxiliary processor as a second driving chip including a controller configured to receive an image signal from the main processor and process the image signal according to the interface specifications of the display module 11.

The memory 13 may include at least one of non-volatile memory and volatile memory. The memory 13 may store data information necessary for operations of the processor 12 or the display module 11. When the processor 12 executes an application stored in the memory 13, an image data signal and/or an input control signal may be transmitted to the display module 11, and the display module 11 may be configured to process the received signal and output image information through a display screen.

The power module 14 may include a power supply module, such as a power adapter or a battery device, and a power conversion module that converts power supplied by the power supply module to generate power required for the operation of the electronic device 10. The power conversion by the power conversion module may include direct current (DC)-DC conversion, alternating current (AC)-DC conversion, and DC-AC conversion and is not limited thereto.

The input module 15 may provide input information to the processor 12 and/or the display module 11. The input module 15 may include not only a physical button, a keyboard, and a microphone, but also various sensor modules. Examples of sensor modules may include touch sensors, pressure sensors, distance sensors, position sensors, digitizers, motion recognition sensors, camera sensors, photodetectors, photoelectric conversion sensors, temperature sensors, as well as biosensors such as blood pressure sensors, blood sugar sensors, electrocardiogram sensors, and/or heart rate sensors.

The non-image output module 16 may receive information except for an image from the processor 12 and provide the information to the user. Examples of the non-image output module 16 may include a sound module, a haptic module, a light-emission module, etc. and may also include other functionally intrinsic modules (for example, a cooling module of a refrigerator, etc.) of the electronic device 10.

The communication module 17 may be configured to perform transmission and reception of information between the electronic device 10 and an external device and may include a receiver and a transmitter. The communication module 17 may include various wireless communication modules, such as a mobile communication module, a WiFi module, a Bluetooth module, etc., or various wired communication modules.

At least of the components of the electronic device 10 described above may be included in the display apparatus 1 (see FIG. 1) according to the embodiments described above. Also, some of individual modules functionally included in one module may be included in the display apparatus 1 and the others may be provided separately from the display apparatus 1. For example, the display apparatus 1 may include the display module 11, and the processor 12, the memory 13, and the power module 14 may be provided as other devices in the electronic device 10, rather than the display apparatus 1. In an example, the power module 14 may be provided in the display apparatus 1 and may provide a power supply to the processor 12 and the memory 13 in the electronic device 10. However, the present disclosure is not limited thereto.

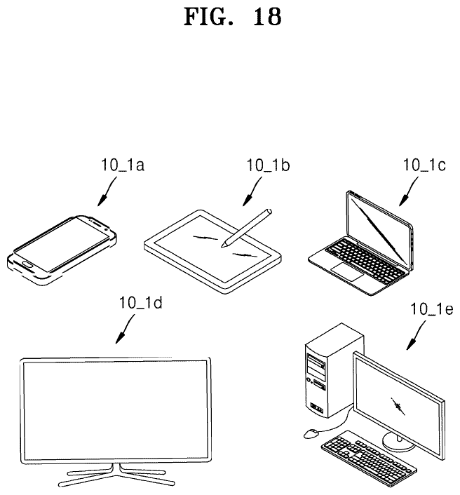

FIGS. 18-20 are schematic diagrams of electronic devices according to various embodiments.

FIG. 18 illustrates examples of electronic devices 10, including a smartphone 10_1a, a tablet PC 10_1b, a laptop computer 10_1c, a TV 10_1d, and a monitor 10_1e for a desk.

The smartphone 10_1a may include an input module, such as a touch sensor, etc., and a communication module, in addition to the display module 11. The smartphone 10_1a may process information received through the communication module or other input modules and display the processed information through a display module 11 of the electronic device 10.

The tablet PC 10_1b, the laptop computer 10_1c, the TV 10_1d, and the monitor 10_1e for a desk may also include a display module and an input module, similarly as the smartphone 10_1a, and may further include a communication module according to cases.

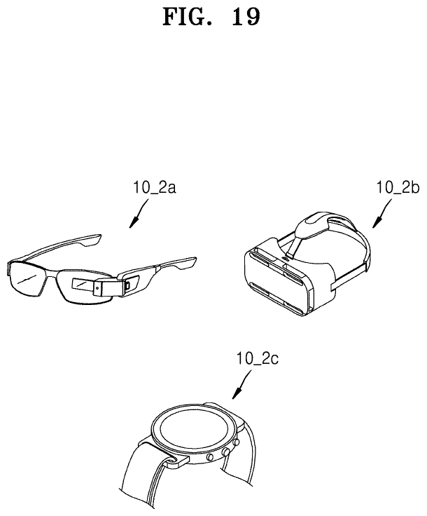

FIG. 19 illustrates examples in which an electronic device 10 including a display module 11 is applied to a wearable electronic device. The wearable electronic device may include smart glasses 10_2a, an HMD 10_2b, a smart watch 10_2c, etc.

The smart glasses 10_2a and the HMD 10_2b may include a display module 11 configured to project a display image and a reflector configured to reflect the projected display screen and provide the display screen to a user's eye, so as to provide a virtual reality (VR) or augmented reality (AR) screen to the user.

The smart watch 10_2c may include a biometric sensor as an input device and may provide biometric information recognized through the biometric sensor to the user through a display module 11.

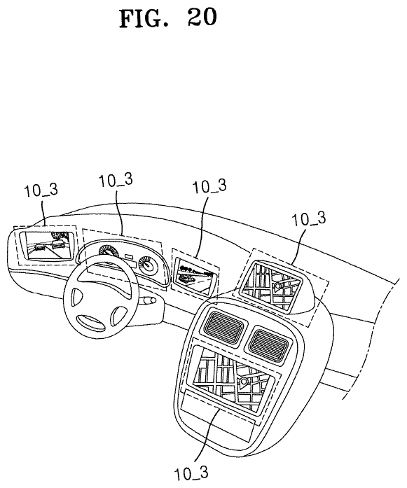

FIG. 20 illustrates examples in which an electronic device 10 including a display module 11 is applied to a vehicle. For example, an electronic device 10_3 may be used as a gauge or a center fascia of the vehicle or may be used as a center information display (CID) arranged on a dashboard of the vehicle or as a room mirror display substituting a side-view mirror.

In one or more embodiments, the electronic device employing the display apparatus 1 (see FIG. 1) according to one or more embodiments may include not only devices mainly used for a screen display, such as an advertisement board, an electronic display board, a game machine, etc., but also various home appliances for displaying information through a display module 11, such as a refrigerator, a laundry machine, a dryer, an air conditioner, a robot cleaner, etc. Also, when a display module 11 has a light-transmission function, the display module 11 may be employed by the electronic device 10, such as a smart window or a transparent display apparatus for displaying a background and a display image together. Types of the electronic device 10 according to one or more embodiments are not limited to the examples described above, and various other electronic devices may also be provided.

According to one or more embodiments as described above, by enhancing the luminance of the area where components are disposed, a display apparatus for displaying a high-quality image and an electronic device comprising the same may be implemented. However, the spirit and scope of the present disclosure is not limited by these effects, aspects, and features.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A display apparatus comprising:
a substrate including a first display area and a second display area, the second display area including a circuit area and a transmission area;
a first pixel circuit in the first display area, and a first light-emitting diode electrically connected to the first pixel circuit; and
a second pixel circuit in the second display area, and a second light-emitting diode electrically connected to the second pixel circuit,
wherein each of the first pixel circuit and the second pixel circuit comprises:
a driving transistor comprising a gate electrically connected to a first node, a first terminal electrically connected to a second node, and a second terminal electrically connected to a third node;
a data writing transistor electrically connected between a data line and the first node;
a first emission control transistor electrically connected between a driving voltage line and the second node; and
a second emission control transistor electrically connected between the third node and a corresponding light-emitting diode from among the first light-emitting diode and the second light-emitting diode, and
wherein the second emission control transistor of the second pixel circuit is maintained in a turn-on state for one frame.

2. The display apparatus of claim 1, wherein:
the first emission control transistor of each of the first pixel circuit and the second pixel circuit is turned on or turned off according to a first emission control signal;
the second emission control transistor of the first pixel circuit is turned on or turned off according to a second emission control signal that is different from the first emission control signal; and
the second emission control transistor of the second pixel circuit is turned on according to a third emission control signal.

3. The display apparatus of claim 2, wherein:
the one frame comprises a first scan period and at least one second scan period;
the first scan period comprises a first period in which the second emission control signal is supplied as an off voltage; and
during the at least one second scan period, the second emission control signal is supplied as an on voltage.

4. The display apparatus of claim 3, wherein the third emission control signal is supplied as the on voltage during the first scan period and the at least one second scan period.

5. The display apparatus of claim 1, wherein the driving transistor comprises an oxide semiconductor layer.

6. The display apparatus of claim 5, wherein the first emission control transistor comprises a silicon semiconductor layer.

7. The display apparatus of claim 1, wherein each of the first pixel circuit and the second pixel circuit further comprises:
a first initialization transistor electrically connected between a reference voltage line and the driving transistor; and
a second initialization transistor electrically connected between an initialization voltage line and the corresponding light-emitting diode from among the first light-emitting diode and the second light-emitting diode.

8. A display apparatus comprising:
a substrate including a first display area and a second display area, the second display area including a circuit area and a transmission area;
a first pixel circuit in the first display area, and a first light-emitting diode connected to the first pixel circuit; and
a second pixel circuit in the second display area, and a second light-emitting diode electrically connected to the second pixel circuit,
wherein each of the first pixel circuit and the second pixel circuit comprises:
a driving transistor comprising a gate electrically connected to a first node, a first terminal electrically connected to a second node, and a second terminal electrically connected to a third node;
a data writing transistor electrically connected between a data line and the first node; and
a first emission control transistor electrically connected between a driving voltage line and the second node,
wherein the first pixel circuit further comprises a second emission control transistor electrically connected between the first light-emitting diode and the third node, and
wherein the third node of the second pixel circuit and the second light-emitting diode are electrically connected via a conductive line.

9. The display apparatus of claim 8, wherein:
the second pixel circuit further comprises a third emission control transistor, the third emission control transistor being electrically connected between the second light-emitting diode and the third node and comprising a gate electrode and a semiconductor layer disposed below the gate electrode.

10. The display apparatus of claim 9, wherein:
the semiconductor layer of the third emission control transistor comprises a channel region overlapping the gate electrode, and a source region and a drain region on opposite sides of the channel region; and
the conductive line electrically connects the source region and the drain region of the third emission control transistor.

11. The display apparatus of claim 8, wherein:
the second emission control transistor in the first pixel circuit comprises a first semiconductor layer comprising a gate electrode, a channel region overlapping the gate electrode, and a source region and a drain region on opposite sides of the channel region; and
the conductive line in the second pixel circuit comprises a second semiconductor layer having a shape corresponding to the first semiconductor layer.

12. The display apparatus of claim 11, further comprising:
an emission control line configured to transmit an emission control signal to the gate electrode of the second emission control transistor,
wherein the emission control line crosses over the second semiconductor layer.

13. The display apparatus of claim 11, further comprising:
an emission control line configured to transmit an emission control signal to the gate electrode of the second emission control transistor; and
an auxiliary emission control line between the substrate and the second semiconductor layer,
wherein the emission control line is electrically connected to the auxiliary emission control line.

14. The display apparatus of claim 8, wherein the driving transistor comprises an oxide semiconductor layer.

15. The display apparatus of claim 14, wherein the first emission control transistor comprises a silicon semiconductor layer.

16. The display apparatus of claim 8, wherein each of the first pixel circuit and the second pixel circuit further comprises:
a first initialization transistor electrically connected between a reference voltage line and the driving transistor; and
a second initialization transistor electrically connected between an initialization voltage line and a corresponding light-emitting diode from among the first light-emitting diode and the second light-emitting diode.

17. An electronic device comprising:
a display apparatus configured to display images;
a memory to store an application; and
a processor configured to execute the application and transmit an image data signal or a control signal to the display apparatus,
wherein the display apparatus comprises:
a substrate including a first display area and a second display area, the second display area including a circuit area and a transmission area;
a first pixel circuit in the first display area, and a first light-emitting diode connected to the first pixel circuit; and
a second pixel circuit in the second display area, and a second light-emitting diode electrically connected to the second pixel circuit,
wherein each of the first pixel circuit and the second pixel circuit comprises:
a driving transistor comprising a gate electrically connected to a first node, a first terminal electrically connected to a second node, and a second terminal electrically connected to a third node;
a data writing transistor electrically connected between a data line and the first node; and
a first emission control transistor electrically connected between a driving voltage line and the second node,
wherein the first pixel circuit further comprises a second emission control transistor electrically connected between the first light-emitting diode and the third node, and
wherein the third node of the second pixel circuit and the second light-emitting diode are electrically connected by a conductive path.

18. The electronic device of claim 17, wherein:
the second pixel circuit further comprises a third emission control transistor electrically connected between the second light-emitting diode and the third node of the second pixel circuit; and
the third emission control transistor is maintained in a turn-on state.

19. The electronic device of claim 17, wherein the third node of the second pixel circuit and the second light-emitting diode are electrically connected via a conductive line.

20. The electronic device of claim 17, wherein the driving transistor comprises an oxide semiconductor layer.
